(19) United States
(12) Patent Application Publication
(10) Pub. No.: US 2026/0206259 A1
(43) Pub. Date: Jul. 16, 2026

(54) SEMICONDUCTOR STRUCTURE WITH ASYMMETRIC SOURCE/DRAIN STRUCTURES AND METHOD OF MANUFACTURING THE SAME

(71) Applicant: TAIWAN SEMICONDUCTOR MANUFACTURING COMPANY LTD., HSINCHU (TW)

(72) Inventors: HONG-CHIH CHEN, CHANGHUA COUNTY (TW); TA-CHUN LIN, HSINCHU (TW); MING-HENG TSAI, TAIPEI CITY (TW); JHON JHY LIAW, HSINCHU COUNTY (TW)

(21) Appl. No.: 19/019,553

(22) Filed: Jan. 14, 2025

(51) Int. Cl. H10D 30/67; H10D 30/00; H10D 30/01; H10D 62/10; H10D 62/13; H10D 64/01; H10D 64/23; H10D 84/01; H10D 84/03; H10D 84/83

(52) U.S. Cl. CPC H10D 30/6735; H10D 30/0191; H10D 30/502; H10D 62/121; H10D 62/151; H10D 64/017; H10D 64/018; H10D 64/251; H10D 84/013; H10D 84/0149; H10D 84/038; H10D 84/832

(57) ABSTRACT

The present disclosure provides a method of forming a semiconductor structure. The method includes: forming a sacrificial gate structure over a nanostructure, wherein the nanostructure protruding from a substrate and including alternating first semiconductor layers and second semiconductor layers; forming a plurality of source openings and drain openings on opposite sides of the nanostructure by partially etching the first semiconductor layers; filling the source opening and the drain opening with a spacer material; partially etching the second semiconductor layers from one side of the nanostructure to form a plurality of source recesses; and forming a source structure and a drain structure at opposing sides of the nanostructure by epitaxially growing a material of the second semiconductor layer from the exposed second semiconductor layers.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of embodiments of the present disclosure are best understood from the following detailed description when read with the accompanying figures. It should be noted that, in accordance with standard practice in the industry, various structures are not drawn to scale. In fact, dimensions of the various structures can be arbitrarily increased or reduced for clarity of discussion.

FIG. 1 is a flow diagram showing a method for forming a semiconductor structure in FIG. 20, in accordance with some embodiments of the present disclosure.

FIGS. 2 to 20 are schematic cross-sectional and perspective views illustrating sequential operations of the method in FIG. 1, in accordance with some embodiments of the present disclosure.

FIG. 21 is a flow diagram showing a method for forming another semiconductor structure in FIG. 32, in accordance with some embodiments of the present disclosure.

FIGS. 22 to 32 are schematic cross-sectional views illustrating sequential operations of the method in FIG. 21, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A gate-all-around (GAA) transistor structure may be formed using one or more photolithography processes, including double-patterning or multi-patterning processes. Double-patterning or multi-patterning processes combine photolithography and self-aligned processes, allowing patterns to be created that have, for example, pitches smaller than what is otherwise obtainable using a single, direct photolithography process.

The present disclosure is related to semiconductor structures (or integrated circuit structures) and methods of forming the same. More particularly, some embodiments of the present disclosure are related to semiconductor structures including asymmetric source/drain epitaxial structures for improving short problem between source/drain via and a gate structure. Furthermore, electrical performance of these semiconductor structures is improved due to such asymmetric structures.

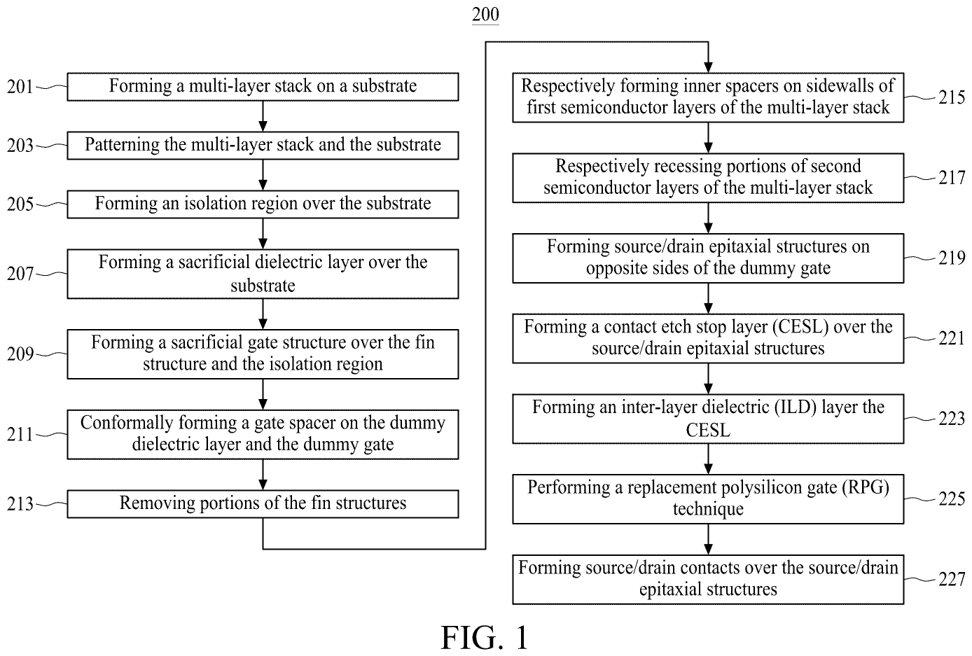

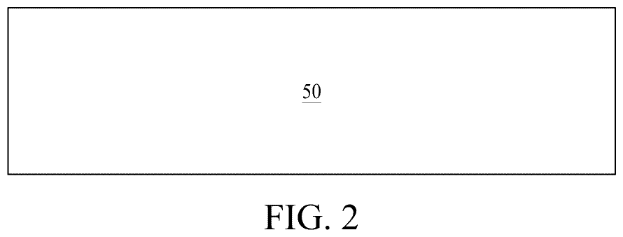

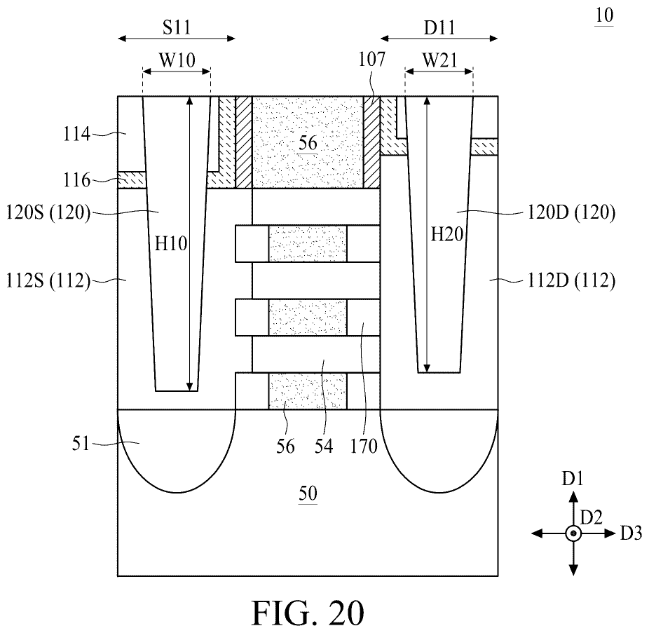

FIG. 1 is a flow diagram showing a method 200 for forming a semiconductor structure 10 in FIG. 20. FIGS. 2 to 20 are schematic cross-sectional and perspective views illustrating sequential operations of the method 200 in FIG. 1. The cross-sectional views may be taken along different directions or along different lines. The method 200 may be used to form a fin field-effect transistor (FinFET) device or a GAA transistor device. The method 200 includes a number of operations and the description and illustration are not deemed as a limitation to the sequence of the operations.

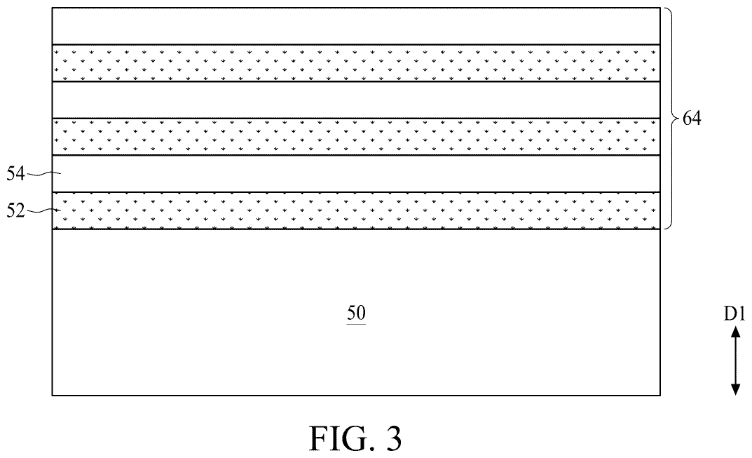

In operation 201 of FIG. 1, a multi-layer stack 64 is formed on a substrate 50, as shown in FIGS. 2 and 3. Referring to FIG. 2, the substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer or a part of a wafer, such as a silicon (Si) wafer. Generally, an SOI substrate is a layer of a semiconductor material formed on an insulator layer. The insulator layer may be, for example, a buried oxide (BOX) layer, a silicon oxide (SiO₂) layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof.

Referring to FIG. 3, the multi-layer stack 64 includes alternating first semiconductor layers 52 and second semiconductor layers 54. The first semiconductor layers 52 and the second semiconductor layers 54 are alternately formed over the substrate 50 along a first direction D1, which may be a thickness direction of the substrate 50. The number of layers of the first semiconductor layers 52 and the second semiconductor layers 54 illustrated in FIG. 3 are merely non-limiting examples. Other numbers of layers are also possible and are fully intended to be included within the scope of the present disclosure. In some embodiments, the first semiconductor layer 52 is formed of an epitaxial material appropriate for forming a channel region of, e.g., a p-type FET, such as silicon germanium (SiₓGe₁₋ₓ, where x can be in the range of 0 to 1). In some embodiments, the second semiconductor layer 54 is formed of an epitaxial material appropriate for forming a channel region of, e.g., an n-type FET, such as silicon. The multi-layer stack 64 will be patterned to form channel regions of an NSFET in subsequent processing. In particular, the multi-layer stack 64 will be patterned to form horizontal nanosheets, with the channel regions of the resulting NSFET including multiple horizontal nanosheets.

The multi-layer stack 64 may be formed by an epitaxial growth process, which may be performed in a growth chamber. In some embodiments, during the epitaxial growth process, the growth chamber is cyclically exposed to a first set of precursors for selectively growing the first semiconductor layers 52, and then exposed to a second set of precursors for selectively growing the second semiconductor layers 54. The first set of precursors includes precursors for a first semiconductor material such as silicon germanium, and the second set of precursors includes precursors for a second semiconductor material such as silicon. In some embodiments, the first set of precursors includes a silicon precursor (e.g., silane) and a germanium precursor (e.g., a germane), and the second set of precursors includes the silicon precursor but omits the germanium precursor.

In some embodiments, the second semiconductor layer 54 serve as channel regions for a subsequently-formed semiconductor structure and the thickness is chosen based on device performance considerations. In some embodiments, the first semiconductor layers 52 will eventually be removed and serve to define a vertical distance between adjacent channel regions for a subsequently-formed multi-gate device and the thickness is chosen based on device performance considerations. Accordingly, the first semiconductor layer 52 may be referred to as a sacrificial layer, and the second semiconductor layer 54 may be referred to as a channel layer.

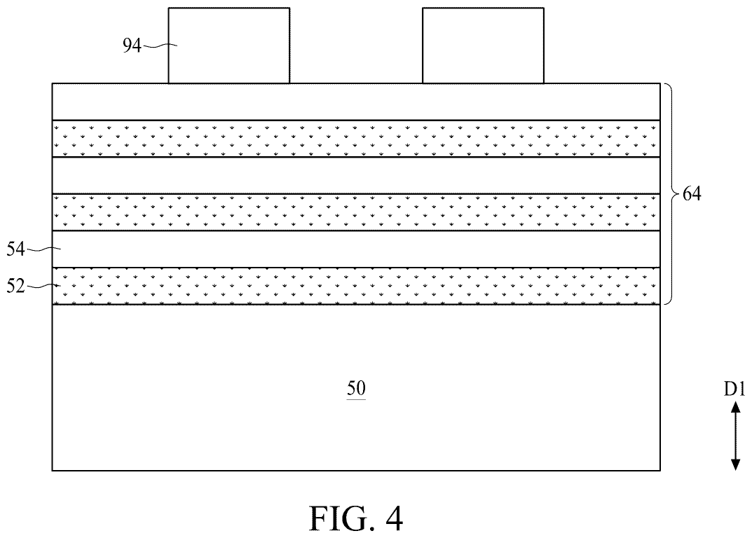

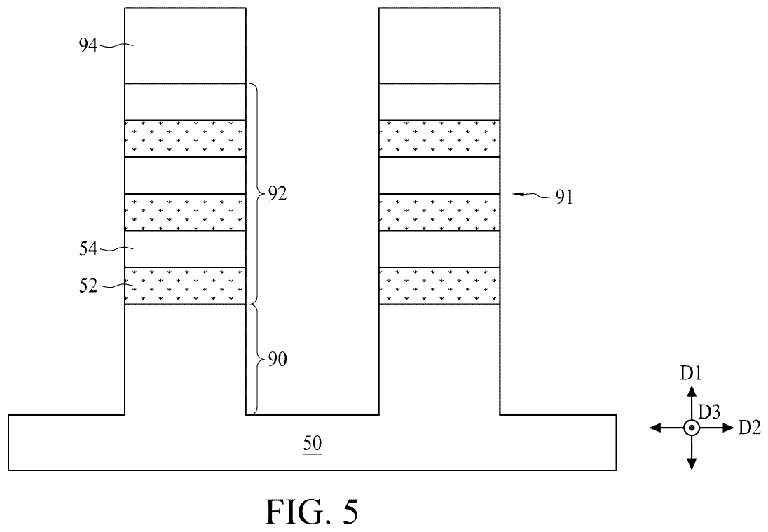

In operation 203 of FIG. 1, the multi-layer stack 64 and the substrate 50 are patterned, as shown in FIGS. 4 and 5. The fin structures 91 may be formed using a double-patterning process or a multi-patterning process. The double-patterning or multi-patterning process includes one or more photolithography operations and etching operations. The photolithography operation may be combined with a self-aligned operation, allowing patterns to be created to have, for example, fine pitches.

Referring to FIG. 4, a mask 94 is formed on the multi-layer stack 64. The mask 94 may be a photoresist pattern or spacers formed using, for example, a self-aligned process.

Referring to FIG. 5, the substrate 50 and the multi-layer stack 64 are etched using the mask 94 as an etching mask. The etching may be any acceptable etching operation, such as a reactive ion etch (RIE), neutral beam etch (NBE), the like, or a combination thereof. In some embodiments, the etching is an anisotropic etching operation. After the etching operation, the multi-layer stack 64 becomes a fin-like stack structure which has multiple protrusions. The protrusion may be referred to as a fin structure 91 including a fin 90 and a nanostructure 92 over the fin 90. The patterned substrate 50 forms multiple fins 90. The fin 90 is formed of a same material as the substrate 50. The fins 90 may protrude from the patterned substrate 50 and arrange along a second direction D2 perpendicular to the first direction. Each of the fin structures 91 extends along a third direction D3 perpendicular to the first direction D1 and the second direction D2. The patterned multi-layer stack 64 forms the nanostructures 92. In the illustrated embodiment, the nanostructure 92 also includes alternating first semiconductor layers 52 and second semiconductor layers 54. The mask 94 may be removed after the fin structures 91 are formed.

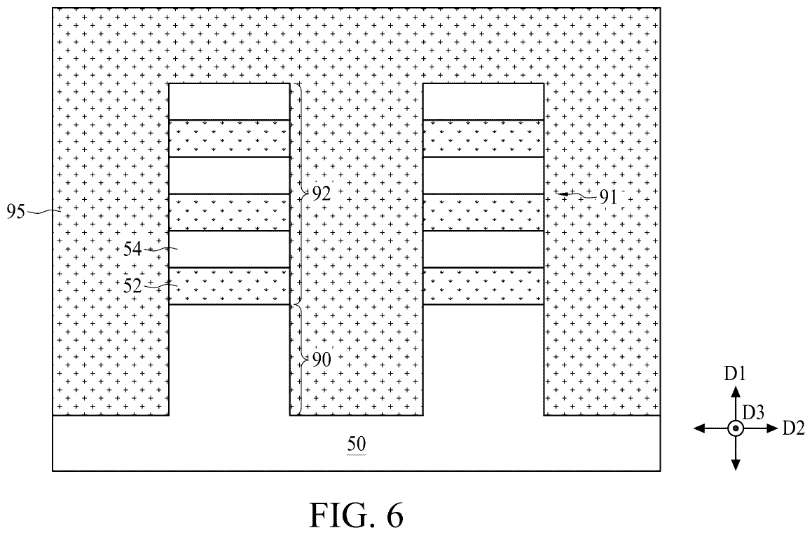

In operation 205 of FIG. 1, an isolation region 96 is formed over the substrate 50, as shown in FIGS. 6 to 8. Referring to FIG. 6, an insulating material 95 is deposited over the substrate 50 using, for example, high density plasma chemical vapor deposition (HDP-CVD), flowable CVD (FCVD), the like, or a combination thereof. The insulating material 95 fills space between adjacent fin structures 91. The insulating material 95 may be silicon oxide, silicon nitride (SiN), phospho-silicate glass (PSG), boro-silicate glass (BSG), boron-doped phospho-silicate glass (BPSG), undoped silicate glass (USG), the like, or a combination thereof. Other insulating materials formed by any acceptable method may be used. An annealing operation may be performed after the insulating material 95 is deposited.

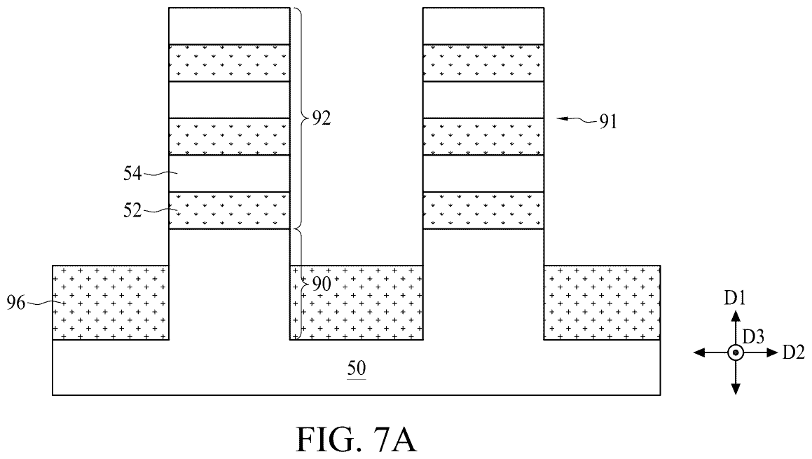

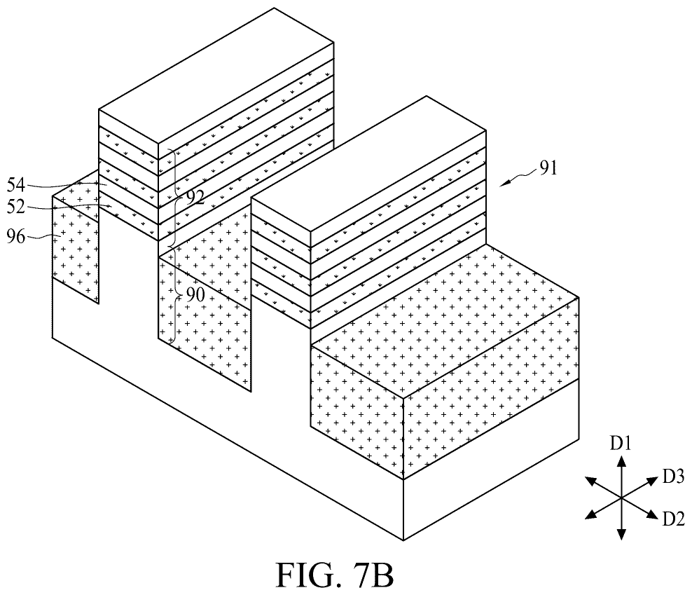

Referring to FIGS. 7A and 7B, FIG. 7B is a schematic perspective view of FIG. 7A. A planarization operation such as chemical mechanical polishing (CMP) is used remove a portion of the insulating material 95 over top surfaces of the topmost second semiconductor layers 54. Subsequently, a removal operation such as an etching back operation is used to recess portions of the insulating material 95 between neighboring fin structures 91. The remaining insulating material 95 forms the isolation region 96. The isolation region 96 may be a shallow trench isolation (STI). The insulating material is recessed until the nanostructure 92 protrudes from between neighboring isolation regions 96. A top portion of the fin 90 may also protrude from between neighboring isolation regions 96. In other embodiments, a top surface of the isolation region 96 is higher than or substantially equal to a top surface of the fin 90 such that the fin 90 is completely surrounded by the insulating material. The isolation region 96 may have a substantially flat surface as illustrated, a convex surface, a concave surface or a combination thereof. In some embodiments, the isolation regions 96 are formed on opposite sides of the fin structure 91.

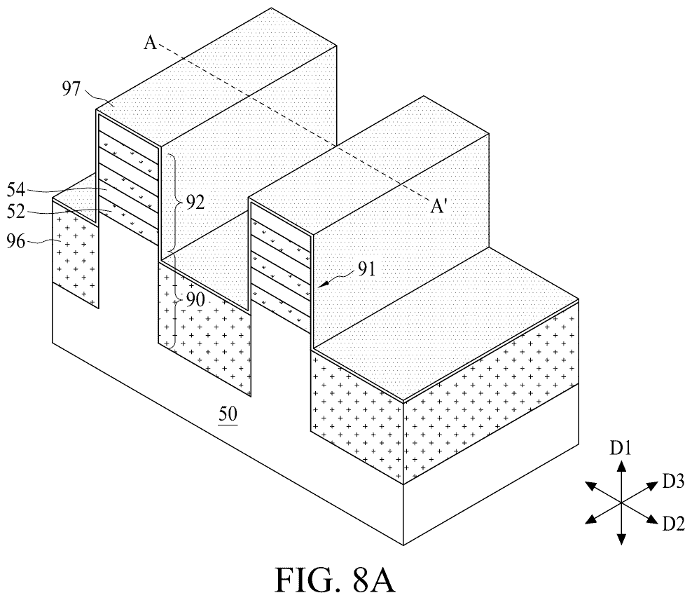

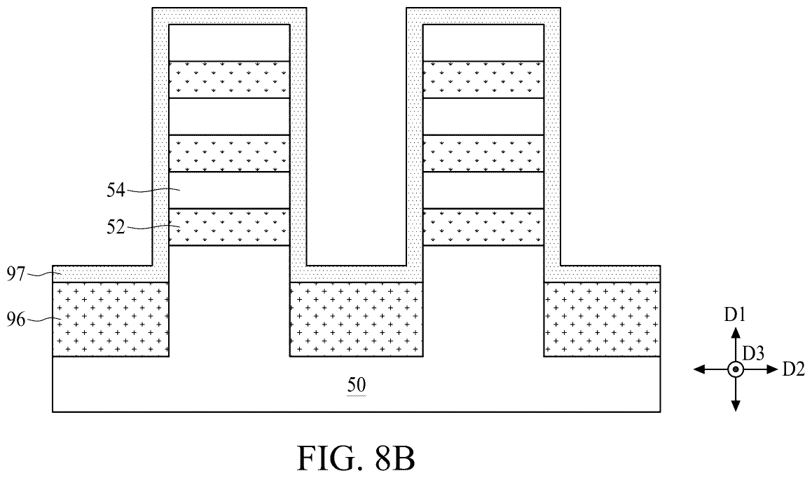

In operation 207 of FIG. 1, a sacrificial dielectric layer or a liner 97 is formed over the substrate 50, as shown in FIGS. 8A and 8B. FIG. 8B is a schematic cross-sectional view along cross-section A-A′ in FIG. 8A. To form the sacrificial dielectric layer 97, a dielectric material is conformally formed on the exposed fin structure 91 and the isolation region 96. The dielectric material includes silicon oxide, silicon nitride, the like, or a combination thereof. The dielectric material may be formed using atomic layer deposition (ALD), CVD, sputtering, thermal growth, or other suitable methods. In some embodiments, a layer of silicon is conformally formed over the fin structure 91 and over an upper surface of the isolation region 96. A thermal oxidization process is performed to convert the deposited silicon layer into a silicon oxide layer, thus forming the sacrificial dielectric layer 97. In other embodiments, the sacrificial dielectric layer 97 includes a dielectric material having a high dielectric constant (k value), for example, greater than 9.0. The dielectric material includes metal oxides such as HfO₂, HfZrOₓ, HfSiOₓ, HfTiOₓ, HfAlOₓ, the like, or a combination thereof. In other embodiments, the sacrificial dielectric layer 97 is made of a low-k dielectric such as carbon doped oxide, an extremely low-k dielectric such as porous carbon doped silicon dioxide, a polymer such as polyimide, the like, or a combination thereof.

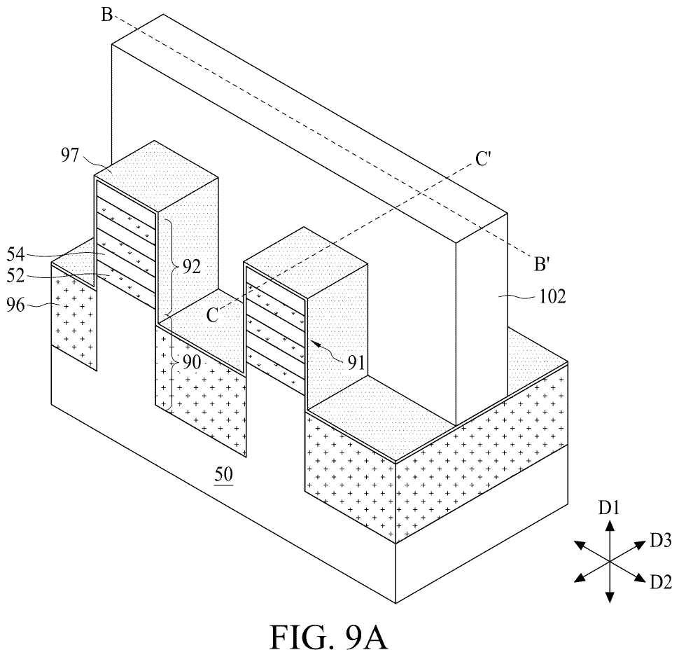

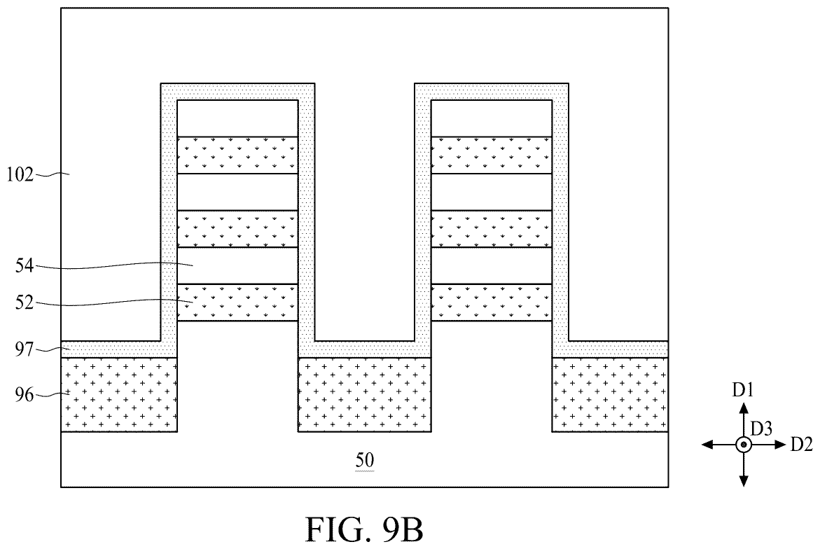

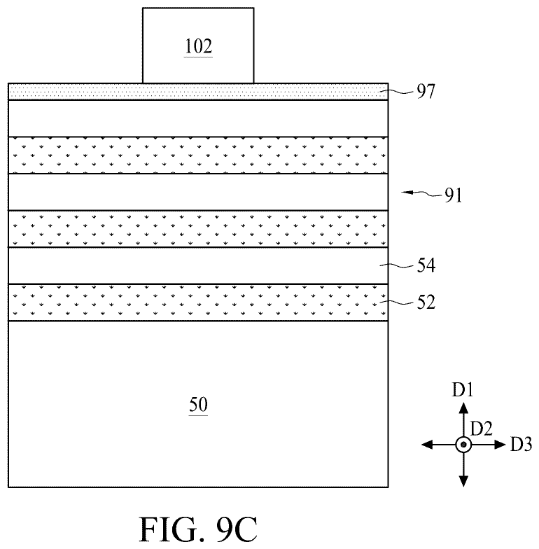

In operation 209 of FIG. 1, a sacrificial gate structure 102 is formed over the fin structure 91 and the isolation region 96, as shown in FIGS. 9A to 9C. FIGS. 9B and 9C are schematic cross-sectional views along cross-sections B-B′ and C-C′ in FIG. 9A, respectively. The sacrificial gate structure 102 may be referred to as a dummy gate structure. To form the sacrificial gate structure 102, a sacrificial gate material is deposited on the sacrificial dielectric layer 97. In some embodiments, the sacrificial gate material includes amorphous silicon (a-Si), polycrystalline-silicon (polysilicon), poly-crystalline silicon-germanium (poly-SiGe), the like, or a combination thereof. The sacrificial gate material may be conductive. The sacrificial gate material may have an etching selectivity greater than that of the insulating material of the isolation region 96. The sacrificial gate material may be formed using physical vapor deposition (PVD), CVD, sputtering, or other suitable methods.

Although not specifically illustrated, one or more photolithography operations and etching operations are used to pattern the sacrificial gate material to form the sacrificial gate structure 102. The sacrificial gate structure 102 covers respective channel regions of the nanostructures 92. In some embodiments, the sacrificial gate structure 102 has a lengthwise direction substantially perpendicular to a lengthwise direction of the fin structures 91. The sacrificial gate structure 102 will be used to define source/drain (S/D) regions from exposed portions of the nanostructures 92.

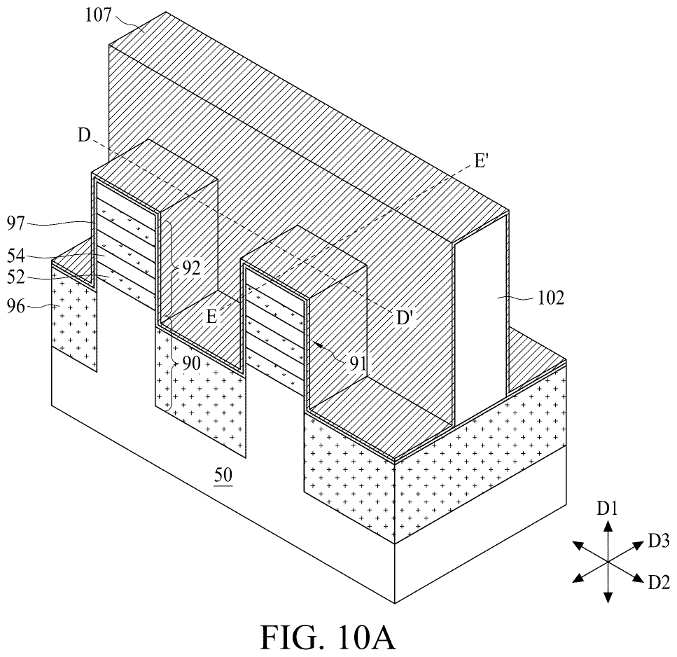

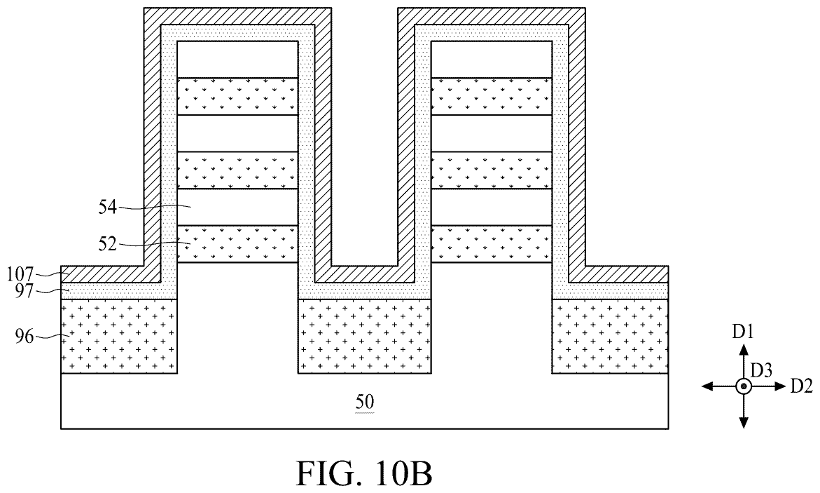

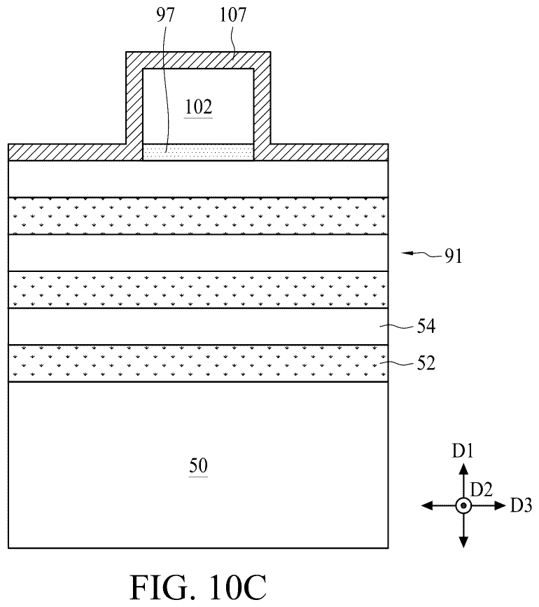

In operation 211 of FIG. 1, a gate spacer 107 is conformally formed on the sacrificial dielectric layer 97 and the sacrificial gate structure 102, as shown in FIGS. 10A to 10C. FIGS. 10B and 10C are schematic cross-sectional views along cross-sections D-D′ and E-E′ in FIG. 10A, respectively. To form the gate spacer 107, a dielectric material such as silicon nitride is deposited over the sacrificial dielectric layer 97, sidewalls and an upper surface of the sacrificial gate structure 102. The dielectric material may be formed using ALD, CVD, sputtering, or other suitable methods. The gate spacer 107 may have a single-layer or multilayer structure.

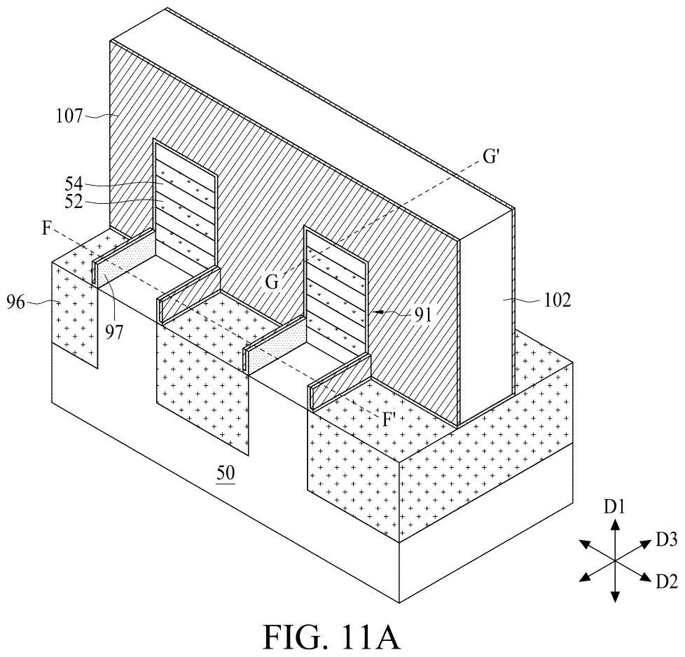

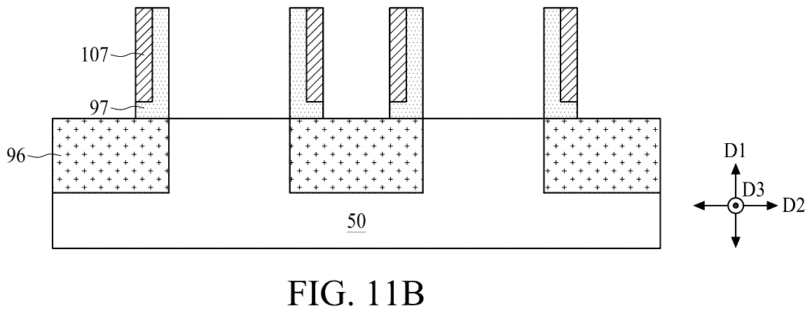

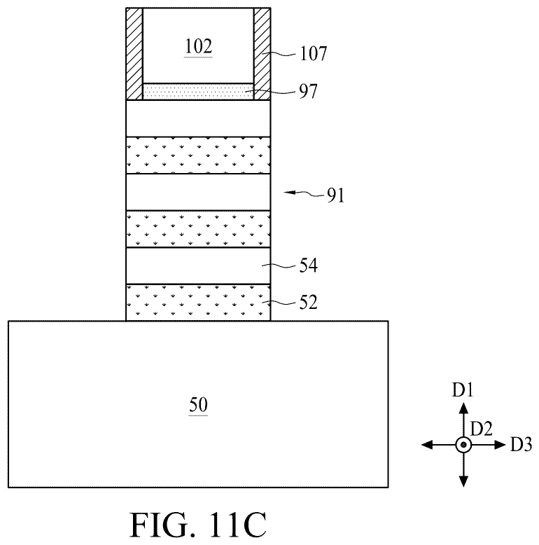

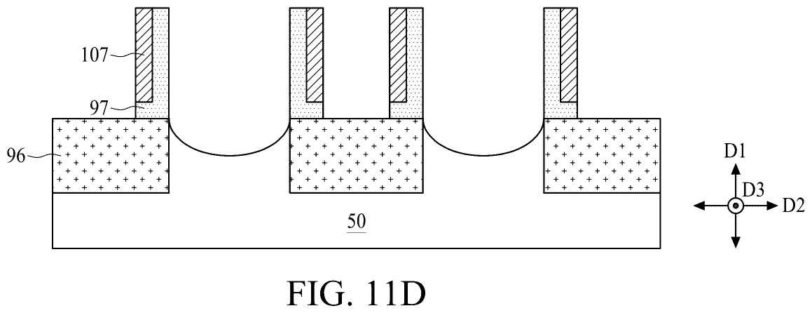

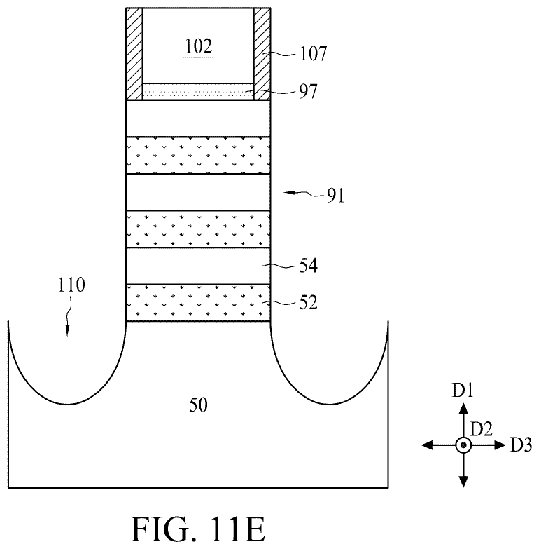

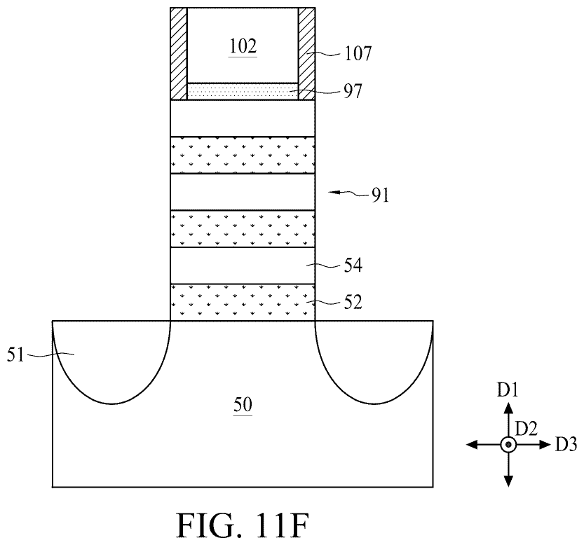

In operation 213 of FIG. 1, portions of the fin structures 91 are removed, as shown in FIGS. 11A to 11F. FIGS. 11B and 11C are schematic cross-sectional views along cross-sections F-F′ and G-G′ in FIG. 11A, respectively.

Referring to FIGS. 11A to 11C, portions of the fin structures 91 exposed by the sacrificial gate structure 102 are removed using an anisotropic etching operation. In some embodiments, the anisotropic etching operation is a strained source/drain (SSD) etching. The SSD etching can be performed in a variety of ways. For example, the SSD etching may be performed by a dry chemical etch with a plasma source and a reaction gas. The plasma source may be an inductively coupled plasma (ICP) etch, a transformer coupled plasma (TCP) etch, an electron cyclotron resonance (ECR) etch, a reactive ion etch (RIE), or the like and the reaction gas may be a fluorine-based gas (such as SF₆, CH₂F₂, CH₃F, CHF₃, or the like), chloride (Cl₂), hydrogen bromide (HBr), oxygen (O₂), the like, or a combination thereof. In some other embodiments, the SSD etching may be performed by a wet chemical etch, such as ammonium peroxide mixture (APM), NH₄OH, TMAH, combinations thereof, or the like. In yet some other embodiments, the SSD etch step may be performed by a combination of a dry chemical etch and a wet chemical etch.

In some embodiment, the anisotropic etching operation is chosen to selectively etch the fin structure 91, the sacrificial dielectric layer 97 and the gate spacer 107 without substantially attacking the sacrificial gate structure 102. During the anisotropic etching operation, portions of the fin structure 91, portions of the sacrificial dielectric layer 97 and portions of the gate spacer 107 are removed using the sacrificial gate structure 102 as an etching mask. In some embodiments, sidewalls of the remaining gate spacer 107 are aligned with sidewalls of the remaining fin structure 91. The gate spacer 107 surrounds the sacrificial gate structure 102 and the sacrificial dielectric layer 97. The sacrificial gate structure 102 and the sacrificial dielectric layer 97 may be collectively referred to as a sacrificial gate structure.

Referring to FIGS. 11D and 11E, in some embodiments, the anisotropic etching operation also recesses into an upper surface of the substrate 50 on opposite sides of the remaining fin structure 91. In other embodiments, another etching operation other than the anisotropic etching operation for selectively etching the fin structure 91 is used to recess the substrate 50. Multiple recesses 110 may be formed extending into the substrate 50. The recesses 110 may be referred to as source/drain recesses. The recesses 110 may have round bottom profiles, but can in practice have various profiles based on the etching operation implemented.

Referring to FIG. 11F, in some embodiments, an initial epitaxial layer 51 is grown in the recess 110. The initial epitaxial layer 51 may be formed using metal-organic CVD (MOCVD), molecular beam epitaxy (MBE), liquid phase epitaxy (LPE), vapor phase epitaxy (VPE), selective epitaxial growth (SEG), a combination thereof, or the like. In some embodiments, the initial epitaxial layer 51 functions as a material layer for a subsequently formed source/drain epitaxial structure. In some embodiments, the initial epitaxial layer 51 is epitaxially grown to a degree that the recess 110 is substantially filled with the initial epitaxial layer 51.

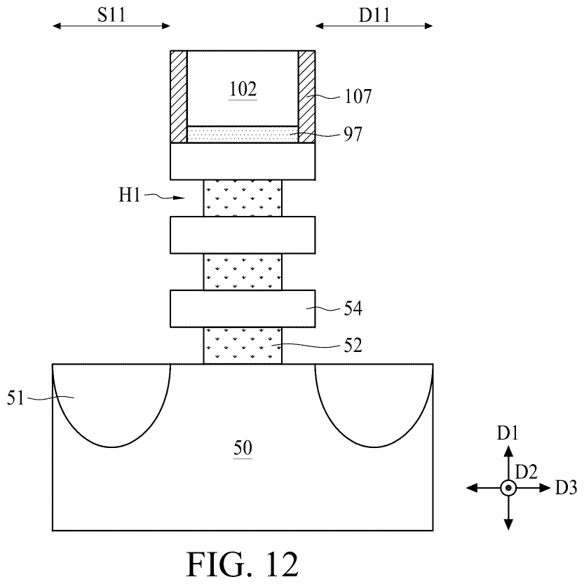

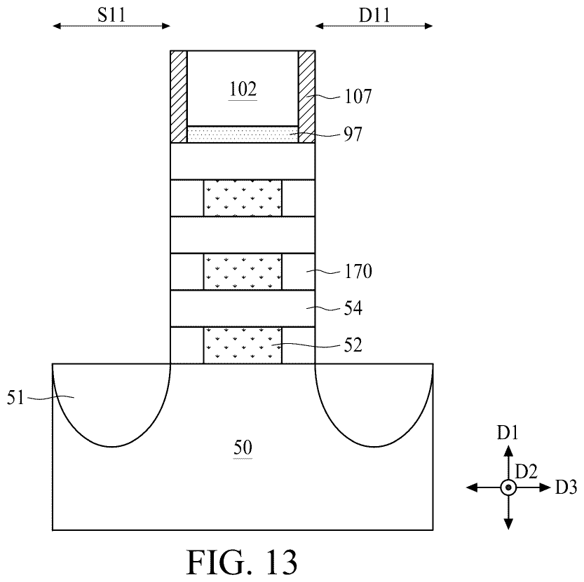

In operation 215 of FIG. 1, inner spacers 170 are respectively formed on sidewalls of the first semiconductor layers 52, as shown in FIGS. 12 and 13. Referring to FIG. 12, one side (e.g., the left side) of the fin structure 91 may be referred to as a source side S11, and the other side (e.g., the right side) of the fin structure 91 opposite to the source side S11 may be referred to as a drain side D11. In some embodiments, one or more etching operations are used to remove portions of the first semiconductor layer 52. The first semiconductor layers 52 are horizontally recessed using a selective etching, resulting in multiple openings H1 each between the second semiconductor layers 54. The openings H1 facing the source side S11 may be referred to as source openings, and the openings H1 facing the drain side D11 may be referred to as drain openings. By way of example and not limitation, the first semiconductor layers 52 are made of SiGe and the second semiconductor layers 54 are made of Si, allowing for the selective etching of the first semiconductor layers 52. In some embodiments, the selective etching includes using an ammonia hydroxide-hydrogen peroxide-water mixture that etches SiGe at a faster etch rate than it etches Si. As a result, the second semiconductor layers 54 laterally extend past opposite end surfaces of the first semiconductor layers 52.

Referring to FIG. 13, to form the inner spacers 170, a dielectric material is respectively formed on sidewalls of the first semiconductor layers 52 to fill the openings H1. In some embodiments, the dielectric material includes a silicon nitride-based material, such as SiN, silicon oxynitride (SiON), silicon oxycarbonitride (SiOCN), silicon carbon nitride (SiCN), the like, or a combination thereof. The dielectric material may be formed using ALD, CVD, or other suitable methods.

After each of the openings H1 is filled with the dielectric material, one or more etching operations are used to remove the dielectric material outside the openings H1, thus forming the inner spacers 170. The etching operations include one or more wet etching and/or dry etching.

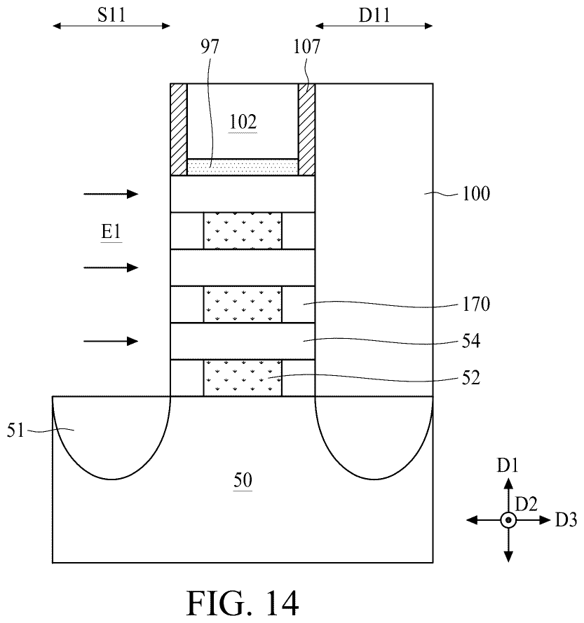

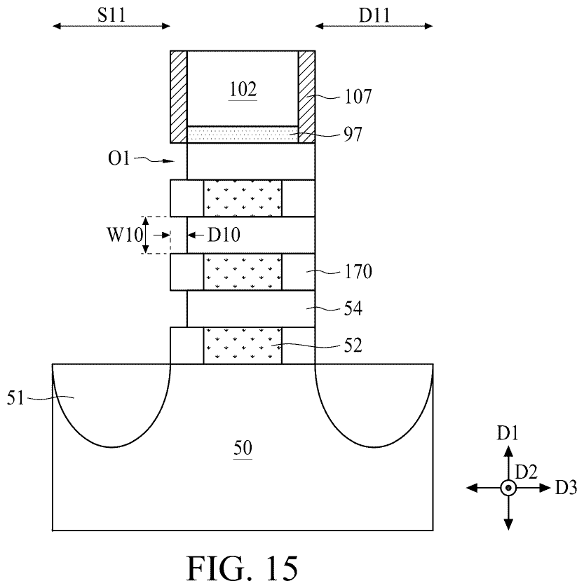

In operation 217 of FIG. 1, portions of the second semiconductor layers 54 are respectively recessed, as shown in FIGS. 14 and 15. Referring to FIG. 14, in some embodiments, a photoresist layer 100 is formed on the initial epitaxial layer 51 at the drain side D11. The photoresist layer 100 covers sidewalls of the first semiconductor layers 52 and the second semiconductor layers 54 facing the drain side D11. In some embodiments, a lateral etching operation E1 is used to remove portions of the second semiconductor layers 54 facing the source side S11. In some embodiments, the lateral etching operation E1 is chosen to selectively etch the second semiconductor layers 54 without substantially attacking the inner spacers 170. In some embodiments, the lateral etching operation E1 includes using hydrogen (H₂), argon (Ar), tetrafluoromethane (CF₄), the like, or a combination thereof. The first semiconductor layer 52 is protected by the inner spacer 170 from being consumed by the lateral etching operation E1.

Referring to FIG. 15, the photoresist layer 100 is removed. In some embodiments, after the second semiconductor layers 54 facing the source side S11 are horizontally recessed by the lateral etching operation E1, multiple source recesses O1 are formed. The source recess O1 may be between the inner spacers 170 or between the inner spacer 170 and the gate spacer 107. The source recesses O1 and the inner spacers 170 are alternately arranged along the first direction D1. In some embodiments, the inner spacers 170 laterally extend past end surfaces of the second semiconductor layers 54 facing the source side S11. In some embodiments, a depth D10 of the source recess O1 is between about 1 nanometer (nm) and 3 nm, and a width D10 of the source recess O1 is between about 2 nm and 5 nm. In some embodiments, on the source side S11, sidewalls of the second semiconductor layers 54 are offset from the sidewalls of inner spacer 170. In some embodiments, the inner spacers 170 and/or the gate spacer 107 serve as a bottom and a top of the source recess O1, while the second semiconductor layer 54 serves as a sidewall of the source recess O1. In contrast to the source side S11, on the drain side D11, sidewalls of the second semiconductor layers 54 are aligned with sidewalls of the inner spacers 170. In some embodiments, the sidewalls of the second semiconductor layers 54 and the sidewalls of the inner spacers 170 are further aligned with the sidewalls of the gate spacer 107.

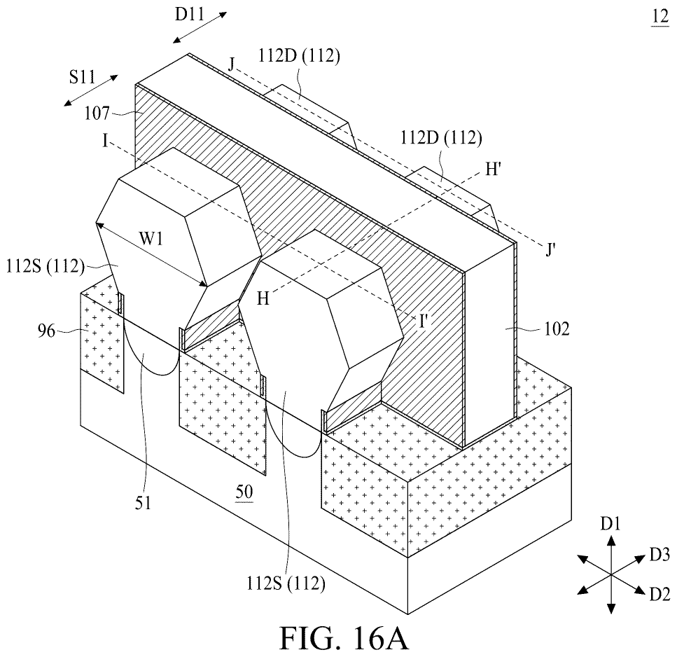

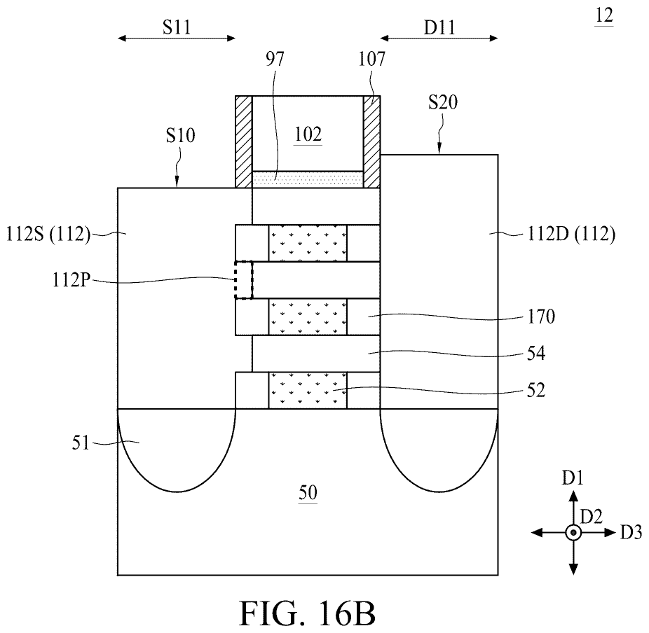

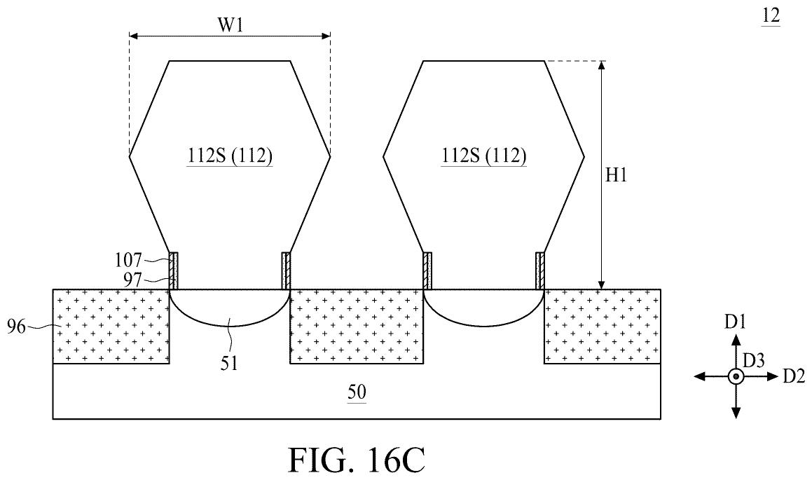

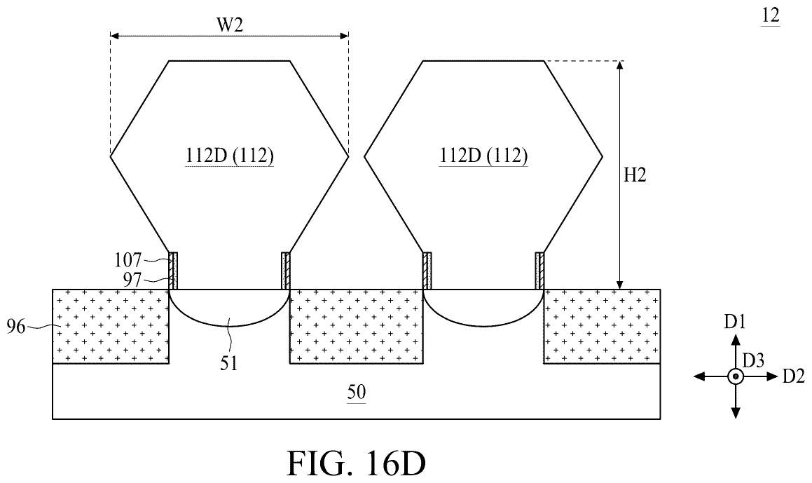

In operation 219 of FIG. 1, source/drain epitaxial structures 112 are formed on opposite sides of the sacrificial gate structure 102, as shown in FIGS. 16A to 16D. FIGS. 16B, 16C and 16D are schematic cross-sectional views along cross-sections H-H′, I-I′ and J-J′ in FIG. 16A, respectively.

Referring to FIGS. 16A and 16B, in some embodiments, the source/drain epitaxial structures 112 are formed using MOCVD, MBE, LPE, VPE, SEG, a combination thereof, or the like. In some embodiments, the source/drain epitaxial structures 112 are continuously formed from the initial epitaxial layer 51. In some embodiments, the source/drain epitaxial structures 112 are formed of a material including silicon germanium. The material gradually fills the recesses 110 and the source recesses O1 and becomes larger in size. As a result, the material forms the source/drain epitaxial structures 112 shown in FIGS. 16A and 16B. The inner spacers 170 may limit the growth of the source/drain epitaxial structures 112. The source/drain epitaxial structures 112 may have various profiles. The profile of the source/drain epitaxial structures 112 shown in FIG. 16A and following figures is merely illustrative. The source/drain epitaxial structures 112 may have surfaces raised from respective end surfaces of the second semiconductor layers 54 and may have multiple facets.

The source/drain epitaxial structures 112 may be in-situ doped during the epitaxial growth operation by introducing doping species including p-type dopants such as boron or BF₂ or n-type dopants such as phosphorus or arsenic. If the source/drain epitaxial structures 112 are not in-situ doped, an implantation process is performed to dope the source/drain epitaxial structures 112. In some embodiments, the source/drain epitaxial structures 112 in an n-type transistor include SiP, while those in a p-type include SiGeB, GeSnB, and/or SiGeSnB. Once the source/drain epitaxial structures 112 are formed, an annealing operation can be performed to activate the p-type dopants or n-type dopants in the source/drain epitaxial structures 112. The annealing operation may be, for example, a rapid thermal anneal (RTA), a laser anneal, a millisecond thermal anneal (MSA), or the like. At this stage, a semiconductor structure 12 is formed.

In some embodiments, a lattice constant of the source/drain epitaxial structures 112 is different from that of the second semiconductor layer 54, such that channel regions in the second semiconductor layer 54 can be strained or stressed by the source/drain epitaxial structures 112 to improve mobility of carriers such as electrons.

The source/drain epitaxial structures 112 are formed such that the sacrificial gate structure 102 is disposed between neighboring pairs of the source/drain epitaxial structures 112. In some embodiments, the gate spacers 107 are used to separate the source/drain epitaxial structures 112 from the sacrificial gate structure 102 by an appropriate lateral distance so that the source/drain epitaxial structures 112 do not short out a subsequently formed gate of the resulting semiconductor structure.

Referring to FIGS. 16C and 16D, FIG. 16C shows the source side S11 of the source/drain epitaxial structures 112, and FIG. 16D shows the drain side D11 of the source/drain epitaxial structures 112. The dielectric layer 97 and the gate spacer 107 are not shown for brevity. The source/drain epitaxial structure 112 at the source side S11 is referred to as a source epitaxial structure 112S, and the source/drain epitaxial structure 112 at the drain side D11 is referred to as a drain epitaxial structure 112D. In some embodiments, a width W1 of the source epitaxial structure 112S is less than a width W2 of the drain epitaxial structure 112D. In some embodiments, a height H1 of the source epitaxial structure 112S is less or lower than a height H2 of the drain epitaxial structure 112D. In some embodiments, a top surface S10 of the source epitaxial structure 112S is lower than a top surface S20 of the drain epitaxial structure 112D. In some embodiments, a size or volume of the source epitaxial structure 112S is less than a size or volume of the source epitaxial structure 112D. That is, the source/drain epitaxial structures 112 have an asymmetric profile in many aspects such width, height, top surface, size, volume, or the like. This is because it takes time for the material layer to fill the recesses 110 facing the source side S11, while there is no recess at the drain side D11. The material layer can directly grow from end surfaces of the second semiconductor layers 54 facing the drain side D11.

Still referring to FIG. 16B, in some embodiments, the source epitaxial structure 112S includes multiple protrusions 112P alternately arranged with the inner spacers 170. The protrusions 112P are located at positions where the recesses 110 used to be. In some embodiments, the source/drain epitaxial structures 112 at opposite sides of the sacrificial gate structure 102 are asymmetric to each other. In some embodiments, the source epitaxial structure 112S is physically and electrically coupled to the second semiconductor layers 54 through the protrusions 112P. During the epitaxial growth operation, the material layer of the source epitaxial structure 112S grows into the source recesses O1. In some embodiments, the protrusions 112P extend form the source epitaxial structure 112S toward the second semiconductor layers 54 along the third direction D3.

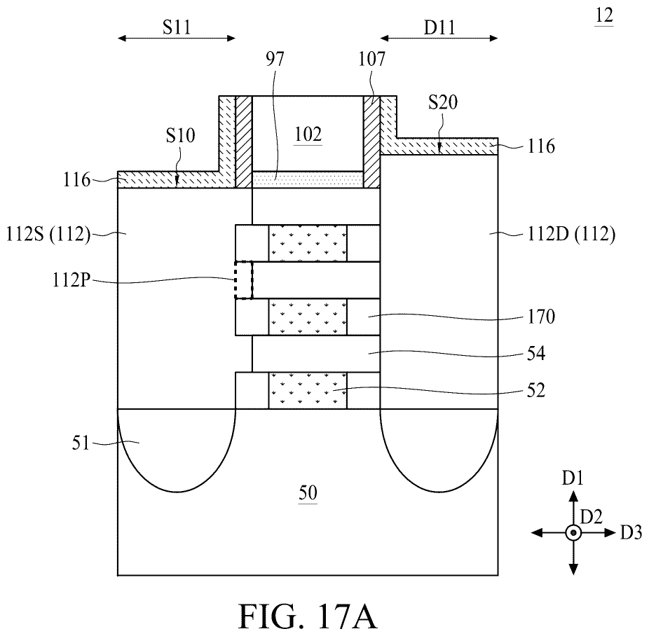

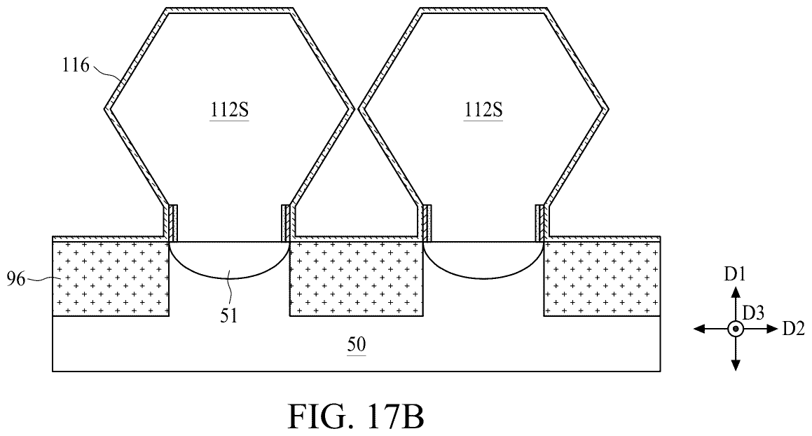

In operation 221 of FIG. 1, a contact etch stop layer (CESL) 116 is formed over the source/drain epitaxial structures 112, as shown in FIGS. 17A and 17B. FIGS. 17A and 17B are schematic cross-sectional views along different directions. In some embodiments, the CESL 116 is formed of SiN, SiON, SiCN, SiOCN, the like, or a combination thereof. The CESL 116 can be conformally deposited on the source/drain epitaxial structures 112, the gate spacer 107 and the sacrificial gate structure 102 using plasma-enhanced CVD (PECVD), low-pressure CVD (LPCVD), ALD, or other suitable methods. The CESL 116 over the gate spacer 107 and the sacrificial gate structure 102 is then removed using one or more etching operations. In some embodiments, the CESL 116 can be a stressed layer. The CESL 116 may have a tensile stress.

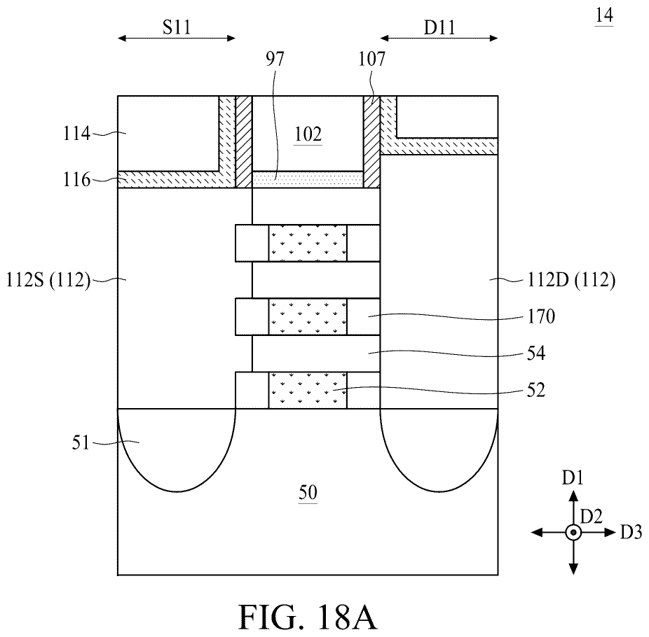

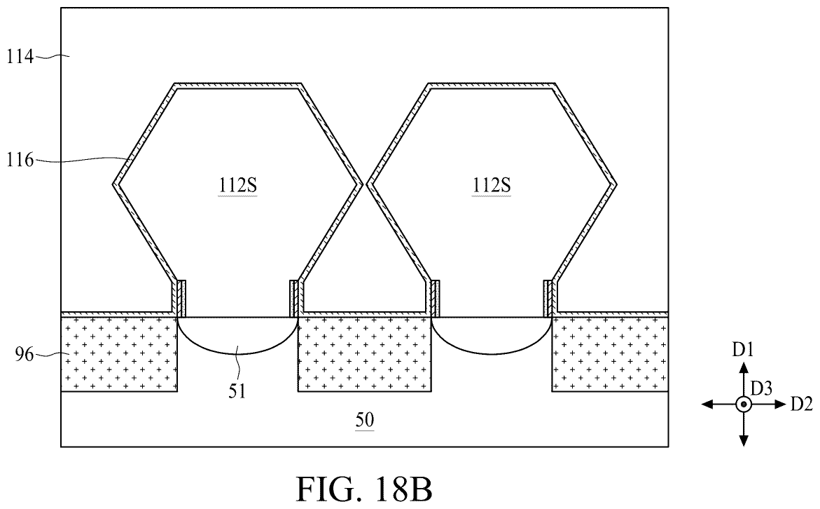

In operation 223 of FIG. 1, a dielectric layer 114 is deposited over the CESL 116, as shown in FIGS. 18A and 18B. FIGS. 18A and 18B are schematic cross-sectional views along different directions. To form the dielectric layer 114, a dielectric material is deposited over the substrate 50. The dielectric material includes silicon oxide, silicon nitride, PSG, BSG, BPSG, USG, the like, or a combination thereof. Other insulating materials formed by any acceptable method may be used. The dielectric material may be formed using CVD, PECVD, FCVD, spin-on coating, or other suitable methods. After the dielectric material is deposited, a planarization operation such as CMP is performed to planarize the dielectric material, thus forming the dielectric layer 114. A top surface of the dielectric layer 114 may be substantially level with top surfaces of the sacrificial gate structure 102 and the gate spacers 107. The top surface of the sacrificial gate structure 102 is exposed through the dielectric layer 114. At this stage, a semiconductor structure 14 is formed.

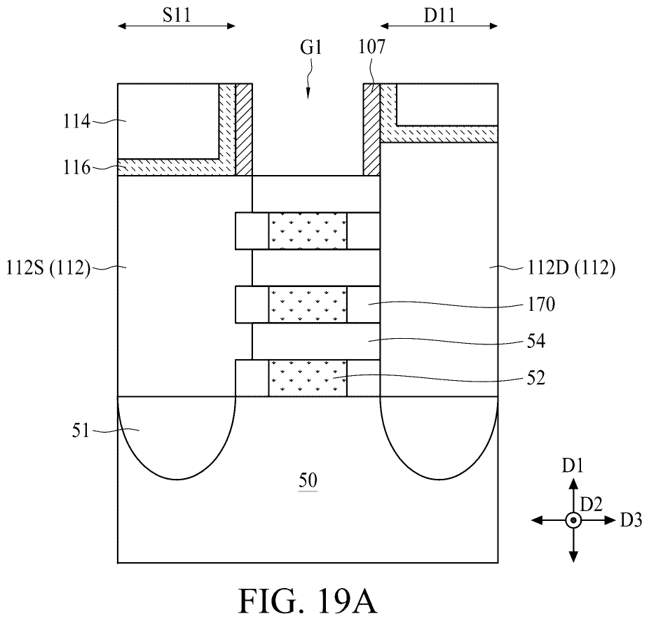

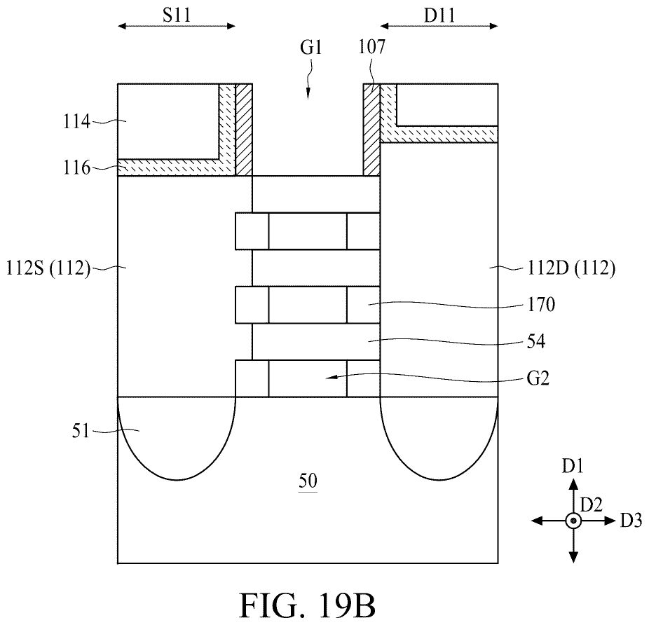

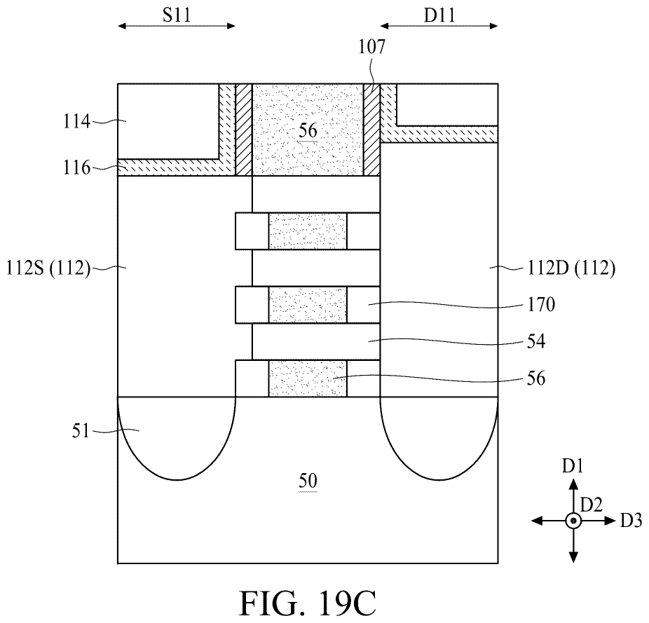

In operation 225 of FIG. 1, a replacement polysilicon gate (RPG) technique is performed on the semiconductor structure 14, as shown in FIGS. 19A to 19C. Referring to FIG. 19A, the sacrificial gate structure 102 is removed is removed using an anisotropic dry etching operation. For example, the dry etching operation uses an etchant that selectively etches the sacrificial gate structure 102 without etching the dielectric layer 114 or the gate spacers 107. The dielectric layer 114 protects the source/drain epitaxial structures 112 during the removal of the sacrificial gate structure 102. A gate trench G1 is formed between the gate spacers 107.

Referring to FIG. 19B, a selective etching operation is used to remove the first semiconductor layers 52 through the gate trench G1. The selective etching operation is chosen to selectively etch the first semiconductor layers 52 without substantially attacking the second semiconductor layers 54. A gate trench G2 is accordingly formed between a pair of inner spacers 170 and between neighboring pairs of second semiconductor layers 54. The gate trenches G2 are between neighboring pairs of source/drain epitaxial structures 112. Such selective etching operation may be referred to as a sheet release process. At this stage, the second semiconductor layers 54 become horizontal nanosheets, suspended over the substrate 50 and between the source/drain epitaxial structures 112. The second semiconductor layers 54 can be interchangeably referred to as nanostructures (nanowire structures, nanosheet structures, etc., depending on their geometry). The nanosheet structures may be collectively referred to as the channel regions.

Referring to FIG. 19C, multiple deposition operations are used to deposit filling materials into the gate trenches G1 and G2 simultaneously to form multiple gate structures 56. Although not specifically illustrated, the deposition operations are performed sequentially, and the filling materials in the deposition operations may be different from each other. For example, gate dielectric layers (not shown) are conformally formed in the gate trenches G1 and G2, respectively. The gate dielectric layer wraps around the second semiconductor layer 54 (i.e., the nanosheet) and lines sidewalls of the inner spacers 170. In some embodiments, the gate dielectric layer includes silicon oxide, silicon nitride, or multilayers thereof. In some embodiments, the gate dielectric layer includes a high-k material (for example, a k value greater than about 7.0) such as hafnium oxide (HfO₂), zirconium oxide (ZrO₂), lanthanum oxide (La₂O₃), hafnium aluminum oxide (HfAlO₂), hafnium silicon oxide (HfSiO₂), aluminum oxide (Al₂O₃), or other suitable materials. The gate dielectric layer may be formed using molecular-beam deposition (MBD), ALD, PECVD or other suitable methods.

Next, one or more conductive materials are deposited into the gate trenches G1 and G2. The conductive material fills the remaining portions of the gate trenches G1 and G2 to form and gate electrodes. The gate electrode and the corresponding gate dielectric layer may be collectively referred to as the gate structure 56. The gate structure 56 is illustrated as a single layer in the example of FIG. 19C and following figures, one skilled in the art will readily appreciate that the gate structure 56 may have a multi-layered structure and include a plurality layers, such as a barrier layer, a work function layer and a filling metal. For example, the barrier layer may be formed conformally over the gate dielectric layer. The barrier layer includes a conductive material such as titanium (Ti), tantalum (Ta), titanium nitride (TiN), tantalum nitride (TaN), the like, or a combination thereof. The work function layer may be formed conformally over the barrier layer. Exemplary p-type work function materials (may also be referred to as p-type work function metals) include TiN, TaN, Ru, Mo, WN, ZrSi₂, MoSi₂, TaSi₂, NiSi₂, WN, other suitable p-type work function materials, or a combination thereof. Exemplary n-type work function materials (may also be referred to as n-type work function metals) include Ti, Ag, TaAl, TaAlC, TiAlN, TaC, TaCN, TaSiN, Mn, Zr, other suitable n-type work function materials, or a combination thereof. The filling metal may be formed over the work function layer. The filling metal includes W, Cu, Co, Al, Ni, Ta, Ti, Mo, Pd, Pt, Ru, Ir, Ag, Au, the like, or a combination thereof. The filling metal may be formed by PVD, electroplating, electroless plating, or other suitable methods. Each gate structure 56 extends over and around the respective second semiconductor layers 54 (i.e., the nanosheet). That is, the gate structures 56 wrap the second semiconductor layers 54. That is, the second semiconductor layers 54 are embedded in the gate structures 56. The inner spacers 170 are disposed on opposite sides of the gate structures 56.

In operation 227 of FIG. 1, source/drain contacts 120 are formed over the source/drain epitaxial structures 112, as shown in FIG. 20. Although not specifically illustrated, the source/drain contacts 120 are formed using one or more photolithography, etching, deposition and/or planarization operations. At the stage, the semiconductor structure 10 is formed.

The source/drain contacts 120 penetrate the dielectric layer 114 and the CESL 116, and extend into the source/drain epitaxial structures 112. The source/drain contact 120 at the source side S11 is referred to as a source contact 120S, and the source/drain contact 120 at the drain side D11 is referred to as a drain contact 120D. The source/drain contacts 120 are electrically coupled to the source/drain epitaxial structures 112. In some embodiments, a width W10 of a top surface of the source contact 120S is greater than a width W20 of a top surface of the drain contact 120D. In some embodiments, a vertical length H10 of the source contact 120S is greater than a vertical length H20 of the drain contact 120D. In some embodiments, a size or volume of the source contact 120S is greater than a size or volume of the drain contact 120D. That is, the source/drain contacts 120 have an asymmetric profile. Although not shown, a gate contact may be formed over and electrically connected to the topmost gate structure 56.

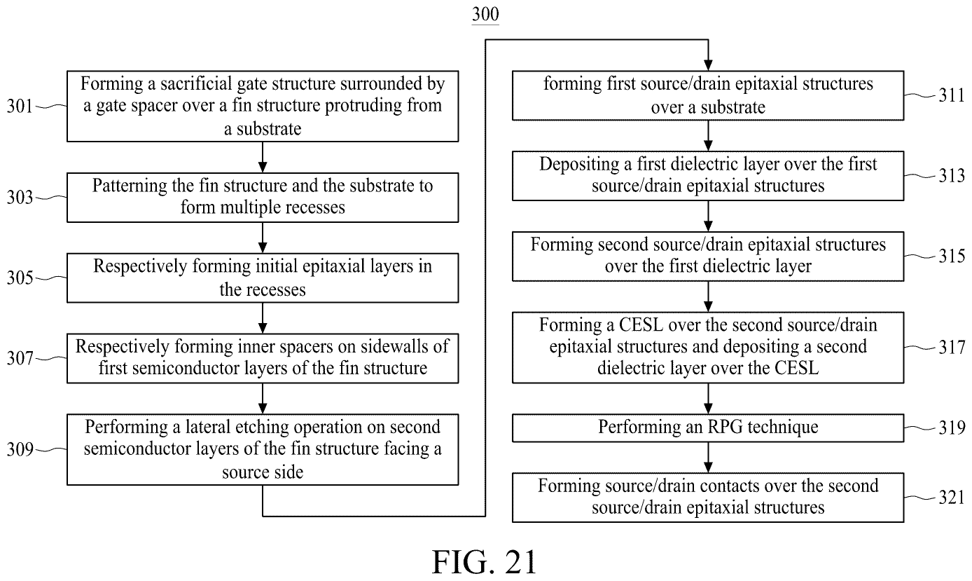

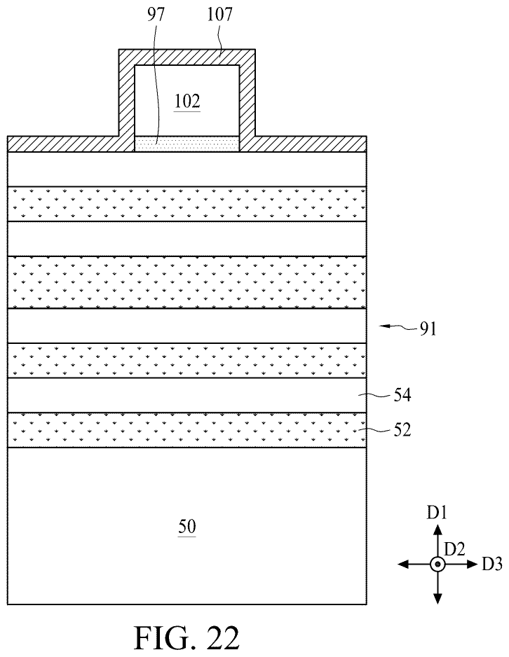

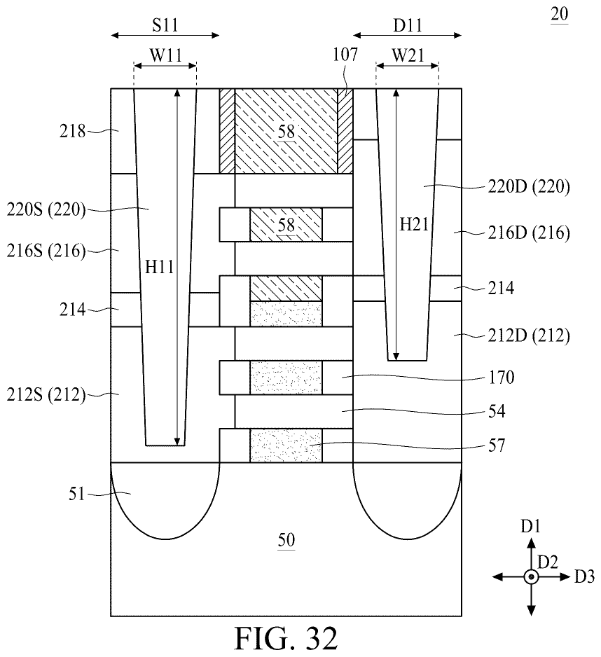

FIG. 21 is a flow diagram showing a method 300 for forming a semiconductor structure 20 in FIG. 32. FIGS. 22 to 32 are schematic cross-sectional views illustrating sequential operations of the method 300 in FIG. 21. The cross-sectional views may be taken along different directions or along different lines. The method 300 may be used to form a complementary field effect transistor (CFET) structure. The method 300 includes a number of operations and the description and illustration are not deemed as a limitation to the sequence of the operations. Some operations of the method 300 may be similar to some operations of the method 200. Repeated operations will only be briefly described for brevity. Furthermore, identical elements are marked with same element numerals.

In operation 301 of FIG. 21, a sacrificial gate structure 102 surrounded by a gate spacer 107 is formed over a fin structure 91 protruding from a substrate 50, as shown in FIG. 22. The sacrificial gate structure 102 is formed on a sacrificial dielectric layer 97.

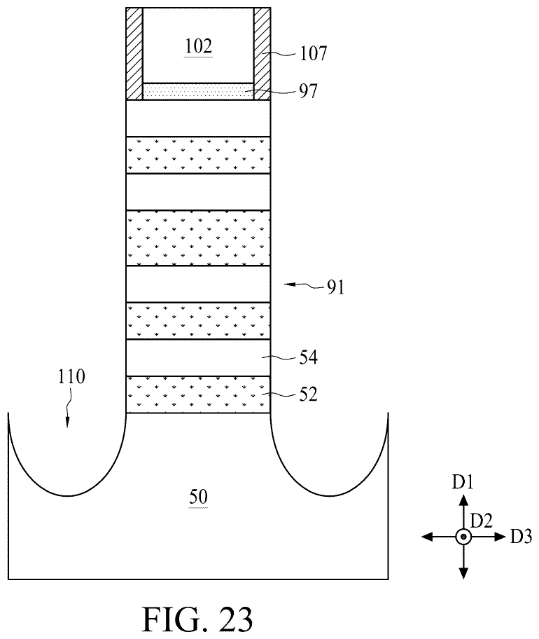

In operation 303 of FIG. 21, the fin structure 91 and the substrate 50 are patterned to form multiple recesses 110, as shown in FIG. 23. In some embodiments, one or more etching operations are used to etch the gate spacer 107 and the fin structure 91. In some embodiments, the etching operation recesses into an upper surface of the substrate 50 on opposite sides of the remaining fin structure 91. The recesses 110 are formed extending into the substrate 50. The recesses 110 may be referred to as source/drain recesses. The fin structure 91 and the substrate 50 may be simultaneously or separately etched.

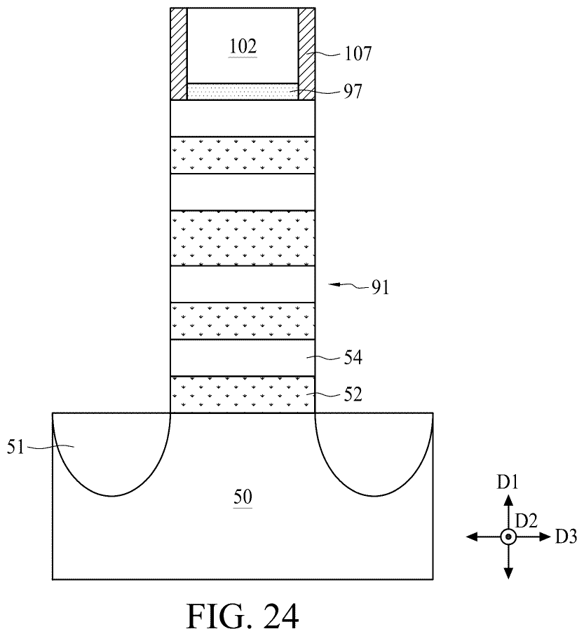

In operation 305 of FIG. 21, initial epitaxial layers 51 are respectively formed in the recesses 110, as shown in FIG. 24. The initial epitaxial layers 51 are formed proximal to the fin structure 91.

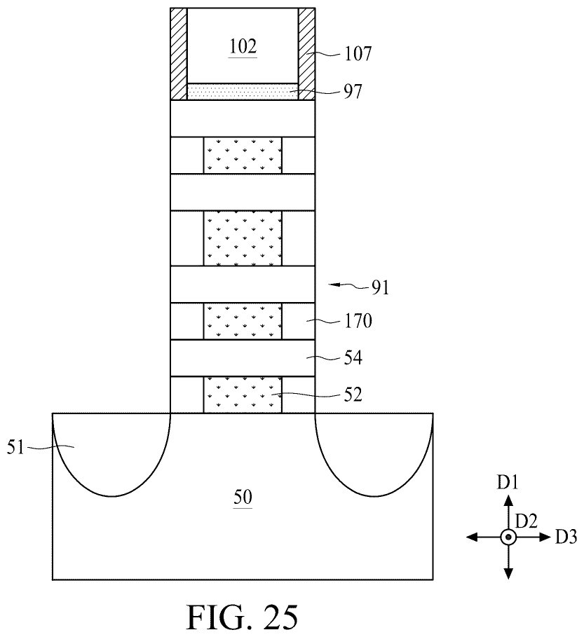

In operation 307 of FIG. 21, inner spacers 170 are respectively formed on sidewalls of the first semiconductor layers 52, as shown in FIG. 25. In some embodiments, one or more etching operations are used to remove portions of the first semiconductor layer 52 to form multiple openings (not shown). Each opening is between the second semiconductor layers 54. Then, a dielectric material is respectively formed on sidewalls of the first semiconductor layers 52 to fill the openings H1, thus forming the inner spacers 170.

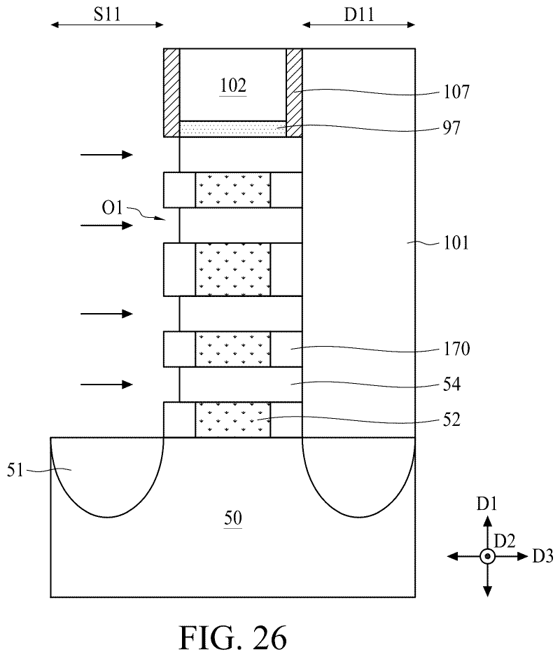

In operation 309 of FIG. 21, a lateral etching operation E1 is performed on the second semiconductor layers 54 facing the source side S11, as shown in FIG. 26. In some embodiments, a photoresist layer 101 is formed on the initial epitaxial layers 51 at the drain side D11. The photoresist layer 101 covers sidewalls of the first semiconductor layers 52 and the second semiconductor layers 54 facing the drain side D11. In some embodiments, portions of the second semiconductor layers 54 are horizontally recessed to form multiple source recesses O1. The source recess O1 may be between the inner spacers 170 or between the inner spacer 170 and the gate spacer 107. The photoresist layer 101 may be removed using a wet clean or ashing operation.

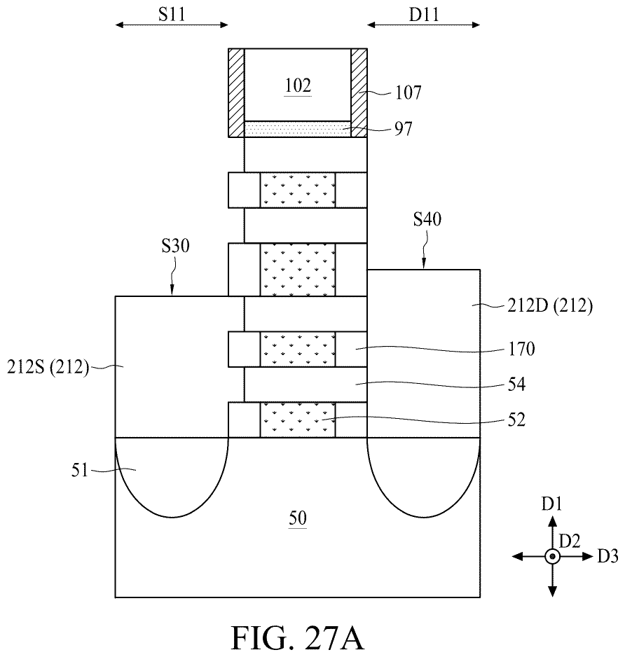

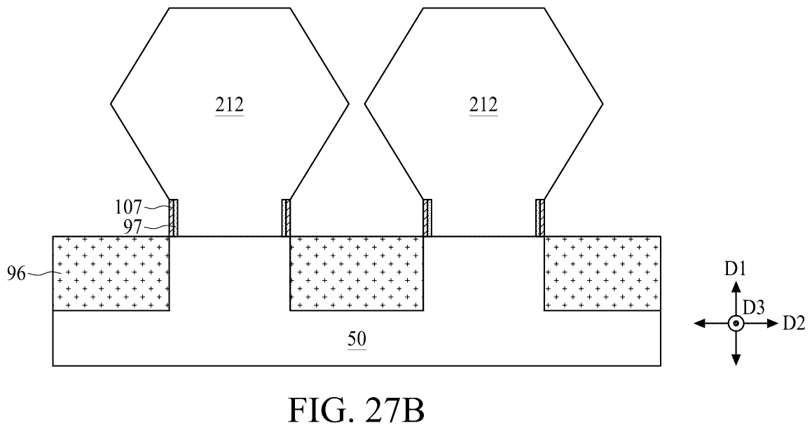

In operation 311 of FIG. 21, first source/drain epitaxial structures 212 are formed over the substrate 50, as shown in FIGS. 27A and 27B. FIGS. 27A and 27B are schematic cross-sectional views along different directions. In some embodiments, a material layer (not shown) including silicon is formed in the recesses 110 and the source recesses O1 using an epitaxial growth operation. The epitaxial growth operation includes vapor-phase epitaxy (VPE), molecular beam epitaxy (MBE), and/or other suitable methods. The epitaxial growth operation may use gaseous and/or liquid precursors, which interact with the epitaxial material of the second semiconductor layer 54. During the epitaxial growth operation, the material layer grows from exposed surfaces of the substrate 50 and the second semiconductor layers 54. The material layer gradually fills the recesses 110 and the source recesses O1 and becomes larger in size. As a result, the material layer forms the first source/drain epitaxial structures 212. The first source/drain epitaxial structures 212 may have various profiles.

In some embodiments, some of the first semiconductor layers 52 and some of the second semiconductor layers 54 are not covered by the first source/drain epitaxial structures 212. The first source/drain epitaxial structure 212 at the source side S11 is referred to as a first source epitaxial structure 212S, and the first source/drain epitaxial structure 212 at the drain side D11 is referred to as a first drain epitaxial structure 212D. In some embodiments, the first source/drain epitaxial structures 212 are doped with p-type species. In some embodiments, a width of the first source epitaxial structure 212S is less than a width of the first drain epitaxial structure 212D. In some embodiments, a height of the first source epitaxial structure 212S is less than a height of the first drain epitaxial structure 212D. In some embodiments, a top surface S30 of the first source epitaxial structure 212S is lower than a top surface S40 of the first drain epitaxial structure 212D. In some embodiments, a size or volume of the first source epitaxial structure 212S is less than a size or volume of the first drain epitaxial structure 212D.

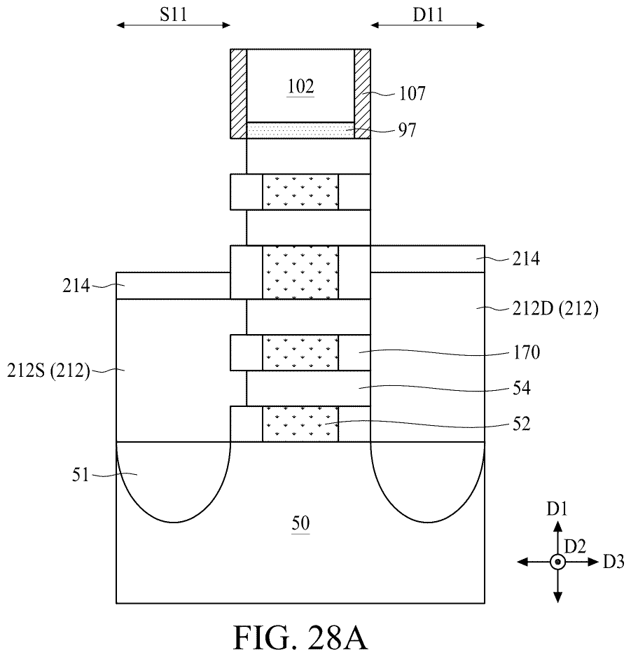

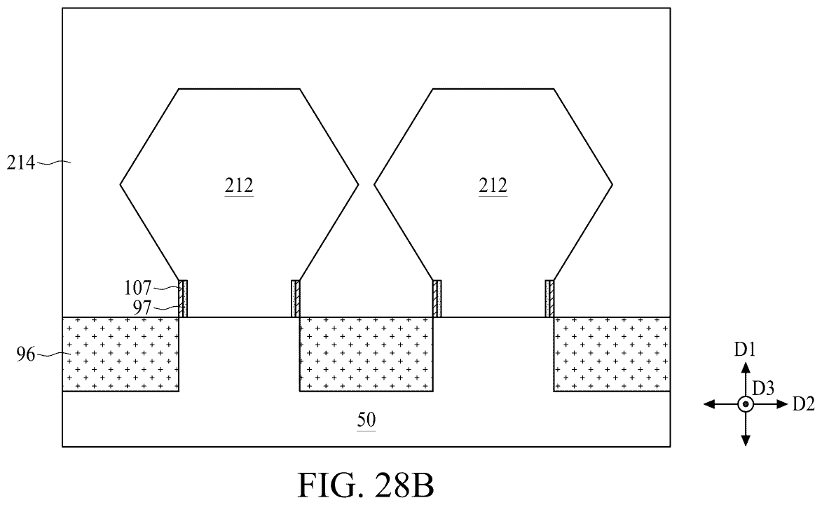

In operation 313 of FIG. 21, a first dielectric layer 214 is deposited over the first source/drain epitaxial structures 212, as shown in FIGS. 28A and 28B. FIGS. 28A and 28B are schematic cross-sectional views along different directions. The first dielectric layer 214 may be formed of a material same as or similar to that of the dielectric layer 114. In some embodiments, some of the first semiconductor layers 52 are exposed through the first dielectric layer 214. In some embodiments, some of the second semiconductor layers 54 are exposed through the first dielectric layer 214.

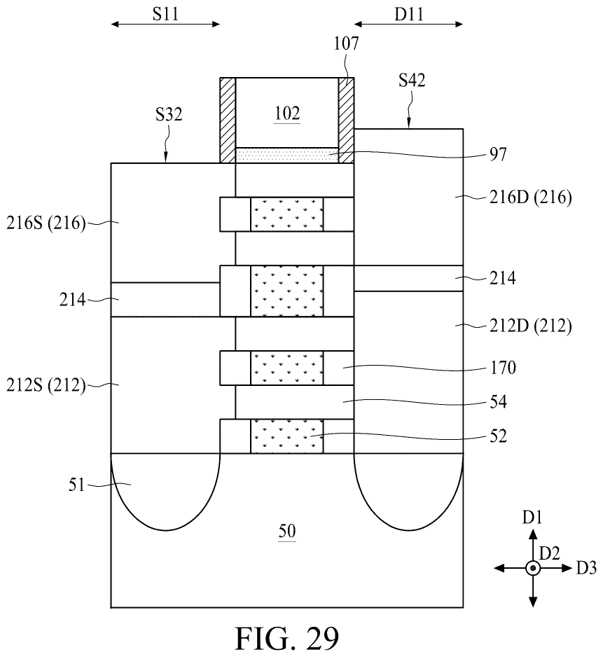

In operation 315 of FIG. 21, second source/drain epitaxial structures 216 are formed over the first dielectric layer 214, as shown in FIG. 29. The second source/drain epitaxial structures 216 may be formed using a method same as or similar to the method for forming the first source/drain epitaxial structures 212. In some embodiments, the second source/drain epitaxial structures 216 are doped with n-type species. The second source/drain epitaxial structure 216 at the source side S11 is referred to as a second source epitaxial structure 216S, and the source/drain epitaxial structure 216 at the drain side D11 is referred to as a second drain epitaxial structure 216D. The cross-sectional view of FIG. 24 does not show complete profiles of the second source epitaxial structure 216S and the second drain epitaxial structure 216D. In some embodiments, a top surface S32 of the second source epitaxial structure 216S is lower than a top surface S42 of the second drain epitaxial structure 216D. In some embodiments, a size or volume of the second source epitaxial structure 216S is less than a size or volume of the second drain epitaxial structure 216D. That is, the second source/drain epitaxial structures 216 have an asymmetric profile in many aspects such width, height, top surface, size, volume, or the like.

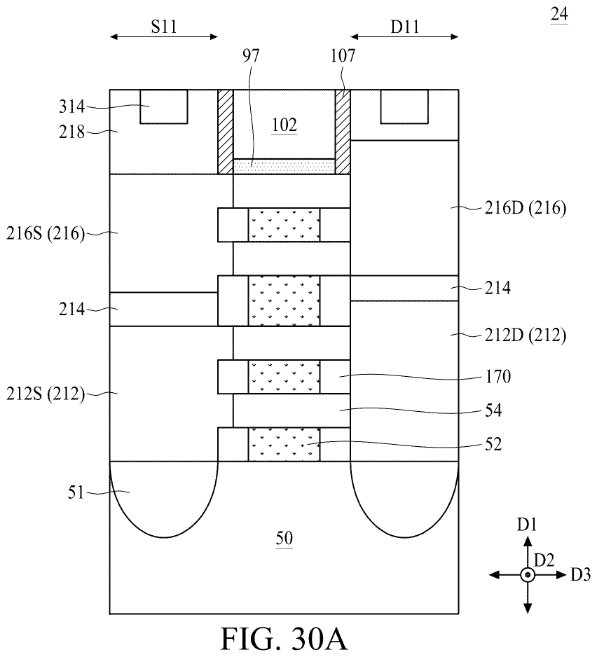

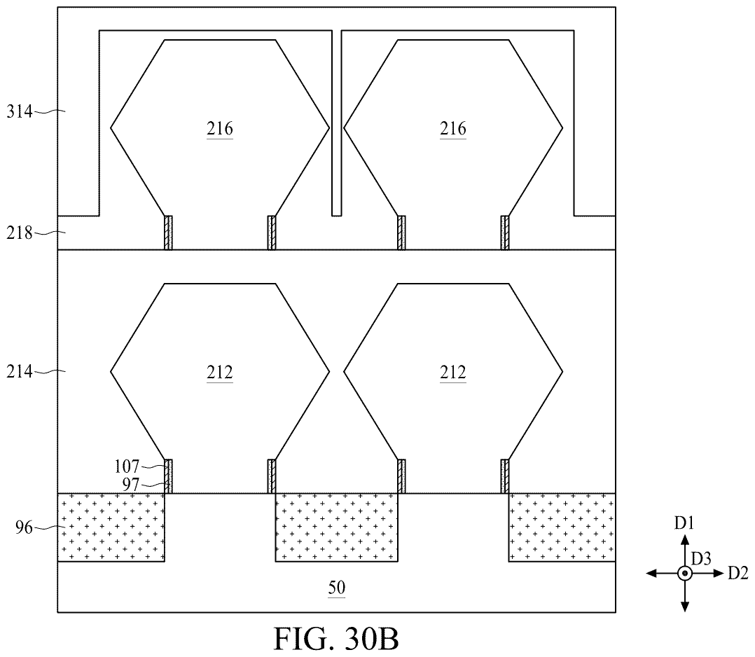

In operation 317 of FIG. 21, a CESL 218 is formed over the second source/drain epitaxial structures 216 and a second dielectric layer 314 is deposited over the CESL 218, as shown in FIGS. 30A and 30B. The CESL 218 may be formed of a material same as or similar to that of the CESL 116, and the second dielectric layer 314 may be formed of a material same as or similar to that of the dielectric layer 114. At this stage, a semiconductor structure 24 is formed.

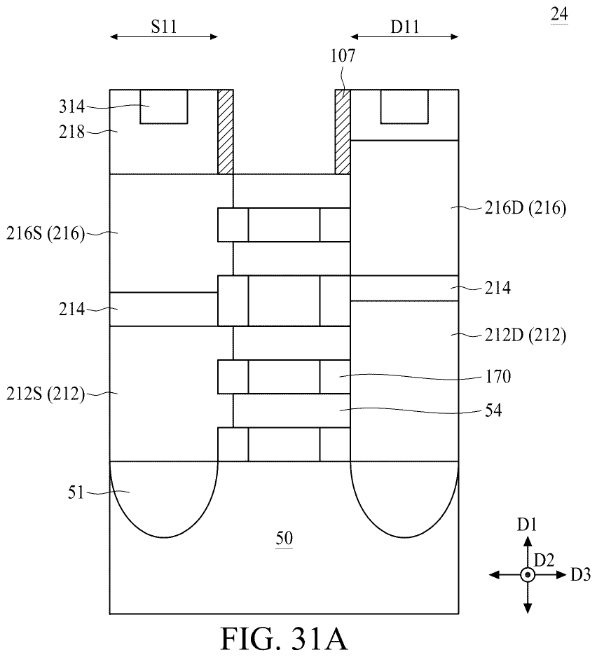

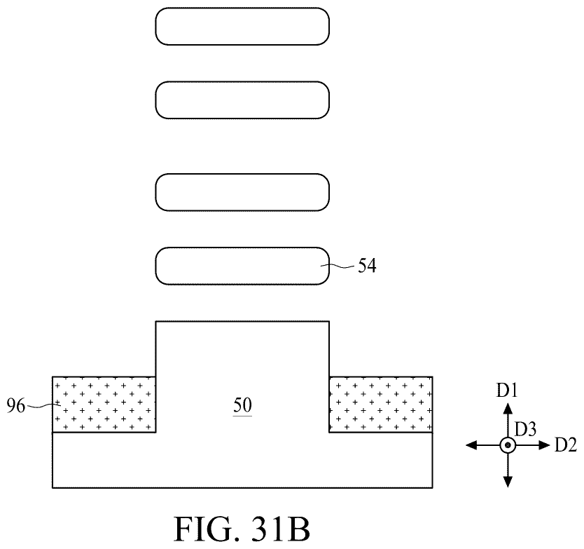

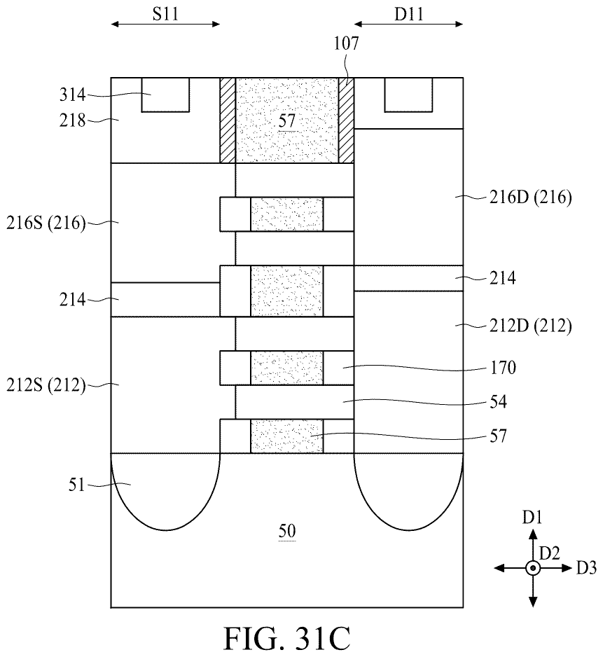

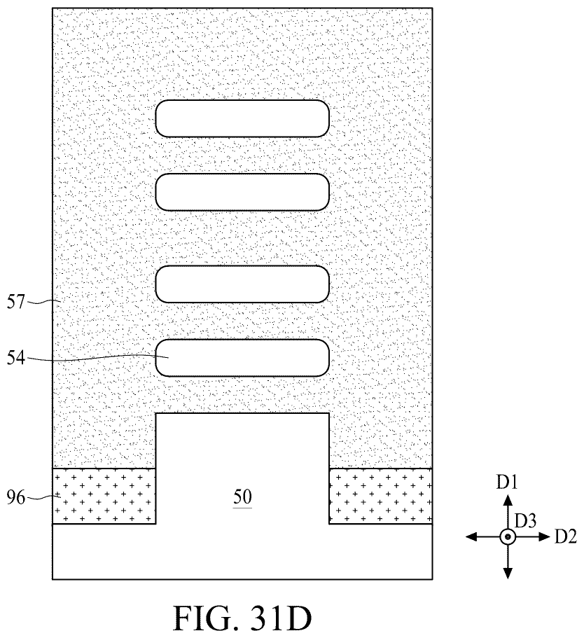

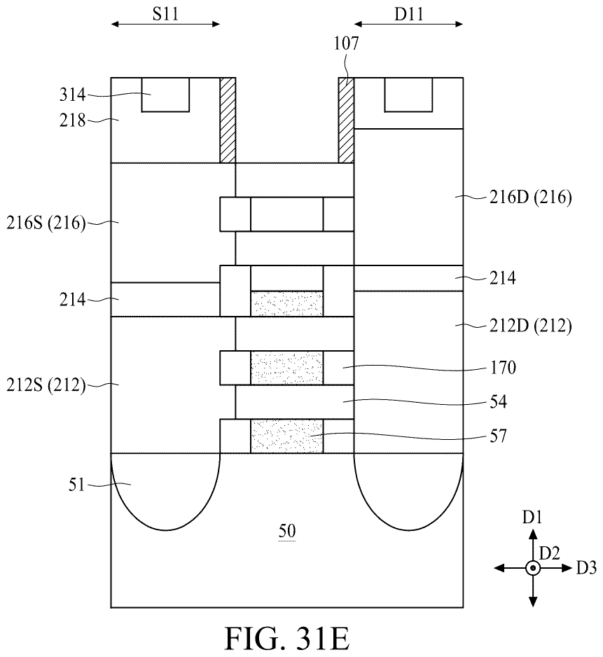

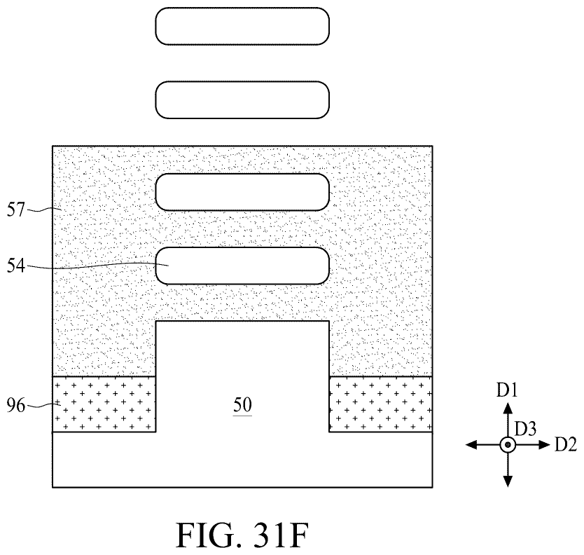

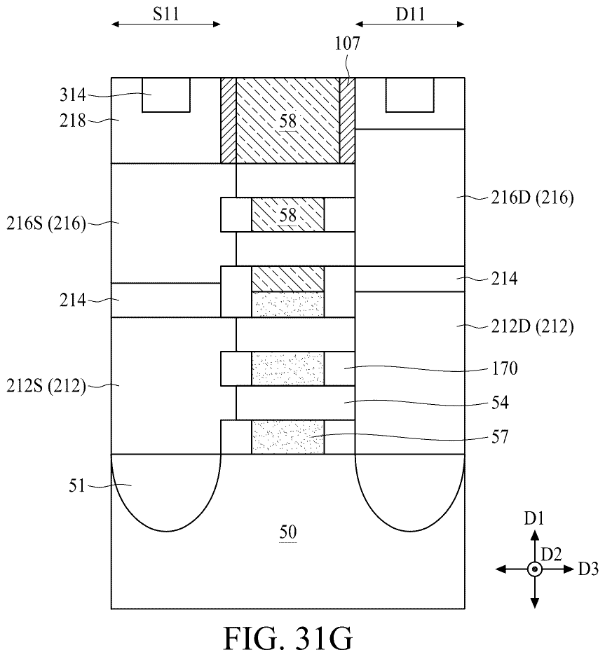

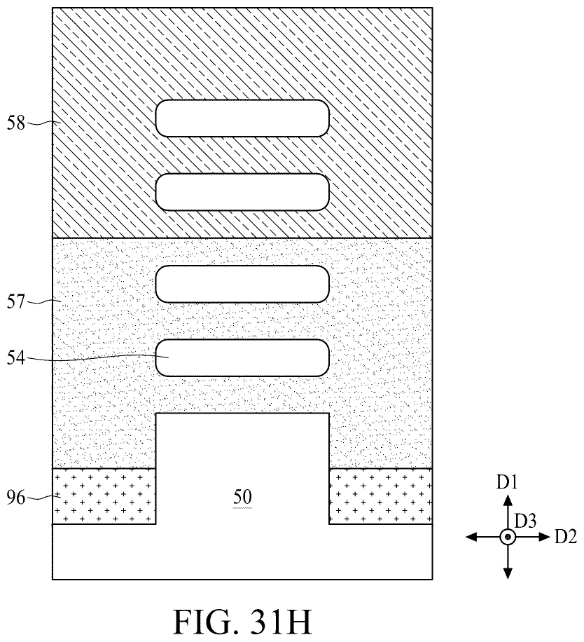

In operation 319 of FIG. 21, an RPG technique is performed on the semiconductor structure 24, as shown in FIGS. 31A to 31H. Referring to FIGS. 31A and 31B, the sacrificial gate structure 102, the sacrificial dielectric layer 97 and the first semiconductor layers 52 are removed using one or more etching operations. The etching operation is chosen to avoid substantially attacking the second semiconductor layers 54. As a result, multiple gate trenches are respectively formed between the gate spacers 107 and the inner spacers 170, as shown in FIG. 31A. The second semiconductor layers 54 become horizontal nanosheets suspended over the substrate 50, as shown in FIG. 31B.

Referring to FIGS. 31C and 31D, one or more deposition operations are used to deposit one or more conductive materials into the gate trenches. The gate trench filled with the conductive materials forms a gate structure 57.

Referring to FIGS. 31E and 31F, portions of the conductive materials are removed to release some gate trenches located at upper portions.

Referring to FIGS. 31G and 31H, one or more deposition operations are used to deposit one or more conductive materials into the re-exposed gate trenches. Such gate trenches filled with the conductive materials form gate structures 58. The gate structures 58 are formed over the gate structures 57.

In operation 321 of FIG. 21, source/drain contacts 220 are formed over the second source/drain epitaxial structures 216, as shown in FIG. 32. At the stage, the semiconductor structure 20 is formed. The source/drain contact 220 at the source side S11 is referred to as a source contact 220S, and the source/drain contact 220 at the drain side D11 is referred to as a drain contact 220D. In some embodiments, the source contact 220S penetrates the CESL 218, the second source epitaxial structure 216S and the first dielectric layer 214 and extends into the first source epitaxial structure 212S. In some embodiments, the drain contact 220D penetrates the CESL 218, the second drain epitaxial structure 216D and the first dielectric layer 214 and extends into the first drain epitaxial structure 212D.

In some embodiments, a width W11 of a top surface of the source contact 220S is greater than a width W21 of a top surface of the drain contact 220D. In some embodiments, a vertical length H11 of the source contact 220S is greater than a vertical length H21 of the drain contact 220D. In some embodiments, a size or volume of the source contact 220S is greater than a size or volume of the drain contact 220D. That is, the source/drain contacts 220 have an asymmetric profile. Although not shown, a gate contact may be formed over and electrically connected to the topmost gate structure 58.

One aspect of the present disclosure provides a method of forming a semiconductor structure. The method includes: forming a sacrificial gate structure over a nanostructure, wherein the nanostructure protruding from a substrate and including alternating first semiconductor layers and second semiconductor layers; forming a plurality of source openings and drain openings on opposite sides of the nanostructure by partially etching the first semiconductor layers; filling the source opening and the drain opening with a spacer material; partially etching the second semiconductor layers from one side of the nanostructure to form a plurality of source recesses; and forming a source structure and a drain structure at opposing sides of the nanostructure by epitaxially growing a material of the second semiconductor layer from the exposed second semiconductor layers.

One aspect of the present disclosure provides another method of forming a semiconductor structure. The method includes: forming a sacrificial gate structure over a fin-like stack structure, wherein the fin-like stack structure protrudes from a substrate and includes alternating first semiconductor layers and second semiconductor layers; forming inner spacers on opposing sides of each of the first semiconductor layers; partially removing the second semiconductor layers from a first side of the fin-like stack structure to form a plurality of recesses; forming a first epitaxial structure of a first conductive type on the first side and a second side of the fin-like stack structure, wherein the second side is opposite to the first side, and the first epitaxial structures have an asymmetric profile or volume on the first side and the second side of the fin-like stack structure; and forming a second epitaxial structure of a second conductive type on the first side and the second side of the fin-like stack structure.

Another aspect of the present disclosure provides a semiconductor structure. The semiconductor structure includes: a nanosheet structure protruding from a substrate; a gate structure wrapping the nanosheet structure and between a plurality of nanosheets of the nanosheet structure; and a source structure and a drain structure on opposite sides of the gate structure. A top surface of the source structure is lower than a top surface of the drain structure.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein be utilized according to the present invention. Accordingly, the appended claims are intended to include within their scope such processes, machines, manufacture, compositions of matter, means, methods and steps.

1. A method of forming a semiconductor structure, comprising:
forming a sacrificial gate structure over a nanostructure, wherein the nanostructure protruding from a substrate and including alternating first semiconductor layers and second semiconductor layers;
forming a plurality of source openings and drain openings on opposite sides of the nanostructure by partially etching the first semiconductor layers;
filling the source opening and the drain opening with a spacer material;
partially etching the second semiconductor layers from one side of the nanostructure to form a plurality of source recesses; and
forming a source structure and a drain structure at opposing sides of the nanostructure by epitaxially growing a material of the second semiconductor layer from the exposed second semiconductor layers.

2. The method of claim 1, wherein the first semiconductor layers include silicon-germanium (SiGe) and the second semiconductor layers include silicon (Si).

3. The method of claim 1, wherein a height of the source structure is lower than a height of the drain structure.

4. The method of claim 1, further comprising:
forming a contact etch stop layer (CESL) over the source structure and the drain structure; and
covering the source structure and drain structure with a dielectric layer.

5. The method of claim 4, further comprising:
removing the sacrificial gate structure and the first semiconductor layers to form multiple gate trenches, while the second semiconductor layers remain and form a plurality of nanosheets.

6. The method of claim 5, further comprising:
forming a metal gate structure in each of the gate trenches, wherein the metal gate structures surround the nanosheets.

7. The method of claim 4, further comprising:
forming a first contact coupled to the source structure and a second contact coupled to the drain structure, wherein
the first contact and the second contact respectively penetrate the CESL and the dielectric layer, and
a width of a top surface of a first contact is greater than a width of a top surface of a second contact.

8. The method of claim 7, wherein a vertical length of the first contact is greater than a vertical length of the second contact.

9. A method of forming a semiconductor structure, comprising:
forming a sacrificial gate structure over a fin-like stack structure, wherein the fin-like stack structure protrudes from a substrate and includes alternating first semiconductor layers and second semiconductor layers;
forming inner spacers on opposing sides of each of the first semiconductor layers;
partially removing the second semiconductor layers from a first side of the fin-like stack structure to form a plurality of recesses;
forming a first epitaxial structure of a first conductive type on the first side and a second side of the fin-like stack structure, wherein the second side is opposite to the first side, and the first epitaxial structures have an asymmetric profile or volume on the first side and the second side of the fin-like stack structure; and
forming a second epitaxial structure of a second conductive type on the first side and the second side of the fin-like stack structure.

10. The method of claim 9, further comprising forming a dielectric layer to separating the first epitaxial structures from the second epitaxial structures.

11. The method of claim 9, wherein the second epitaxial structure is over the first epitaxial structure.

12. The method of claim 9, wherein the partial removal of the second semiconductor layer is performed by a lateral etching back operation.

13. The method of claim 9, wherein
the first epitaxial structure at the first side is a source structure, and the first epitaxial structure at the second side of the stack structure is a drain structure, and
a width of the drain structure is greater than a width of the source structure.

14. The method of claim 9, wherein the inner spacer prevents the first semiconductor layer from being consumed during the partial removal of the second semiconductor layer.

15. A semiconductor structure, comprising:
a nanosheet structure protruding from a substrate;
a gate structure wrapping the nanosheet structure and between a plurality of nanosheets of the nanosheet structure; and
a source structure and a drain structure on opposite sides of the gate structure, wherein
a top surface of the source structure is lower than a top surface of the drain structure.

16. The semiconductor structure of claim 15, wherein the source structure includes a plurality of protrusions extending from the source structure toward the nanosheet structure.

17. The semiconductor structure of claim 15, wherein a height of the source structure is less than a height of the drain structure.

18. The semiconductor structure of claim 15, further comprising:
a CSEL layer, disposed on the source structure and the drain structure;
a dielectric layer, disposed on the CSEL layer;
a first contact, vertically extending into the source structure; and
a second contact, vertically extending into the drain structure, wherein
the first contact and the second contact respectively penetrate the CSEL capping layer and the dielectric layer.

19. The semiconductor structure of claim 18, wherein a width of a top surface of the first contact is greater than a width of a top surface of the second contact.

20. The semiconductor structure of claim 18, wherein a vertical length of the first contact is greater than a vertical length of the second contact.
